(19) United States
(12) Patent Application Publication
(10) Pub. No.: US 2026/0347690 A1
(43) Pub. Date: Nov. 5, 2026

(54) LUMINESCENT WAVEGUIDE ENCODED LATTICES (LWELS)

(71) Applicants: MCMASTER UNIVERSITY, Hamilton (CA); CAMBRIDGE ENTERPRISE LIMITED, Cambridge, Cambridgeshire (GB)

(72) Inventors: Kathryn BENINCASA, Hamilton (CA); Rachel EVANS, Cambridge (GB); Takashi LAWSON, Cambridge (GB); Helen TUNSTALL-GARCIA, Cambridge (GB); Kalaichelvi SARAVANAMUTTU, Hamilton (CA)

(21) Appl. No.: 19/491,442

(22) PCT Filed: Jun. 7, 2024
(86) PCT No.: PCT/EP2024/065828

§ 371 Date: Dec. 9, 2025

Related U.S. Application Data
(60) Provisional application No. 63/472,150, filed on Jun. 9, 2023.

(51) Int. Cl. C09K 11/06; C09K 11/02; H10F 77/45

(52) U.S. Cl. CPC C09K 11/06; C09K 11/025; H10F 77/45; C09K 2211/1033; C09K 2211/1048

(57) ABSTRACT

The disclosure relates to the design and preparation of a luminescent polymer film and in particular, to improve the efficiency of photovoltaic (PV) cells under diffuse lighting conditions and methods of making and uses thereof.

### RELATED APPLICATIONS

This application is a U.S. National Stage Application filed under 35 U.S.C. 371, claiming priority to International Application No. PCT/EP2024/065828 filed on 7 Jun. 2024, which claims priority to U.S. Provisional Application No. 63/472,150 filed on 9 Jun. 2023, the entireties of which are incorporated herein by reference.

### INTRODUCTION

The present invention relates to a method of fabricating a thin luminescent polymer film, and to a thin luminescent polymer film obtained or obtainable by such a method. The present invention also relates to a photosensitive sol for the fabrication of a thin luminescent polymer film, to a method of preparing the sol, to a method of fabricating a thin luminescent polymer film, and to a thin luminescent polymer film obtained or obtainable by such a method. The present invention also relates to a thin luminescent polymer film, to an apparatus comprising a thin luminescent polymer film and a photovoltaic cell, as well as to various uses and applications.

### BACKGROUND

The Internet of Things (IoT) underpins our future smart world where electronic devices are integrated with wireless communication. The rapid growth of the IoT ecosystem is expected to lead to one trillion interconnected devices by 2035. Many of these devices will need to be standalone and portable, creating an urgent demand for off-grid power sources.

Although rechargeable batteries offer a partial solution, the reduction in performance with each recharge cycle, and the need to access every IoT device to complete a recharge cycle, is particularly onerous for embedded IoT nodes in isolated locations.

Commercial crystalline silicon (c-Si) PV cells have significant potential for recycling indoor artificial light to perpetually power the wireless electronics that form the basis of the IoT. This is primarily due to their cost-effectiveness and abundance.

However, c-Si PV cells are optimized to work efficiently under sunlight, whose spectral output is very different to that of artificial light sources. Ambient indoor sources, where the frontrunner is white light-emitting diode (WLED) lighting, have emission spectra solely in the visible wavelength range. This implies that the optimum bandgap for indoor photovoltaics (IPV) is in the range of 1.9-2.0 eV.

In addition to the spectral differences between indoor and outdoor illumination, c-Si PV cells perform poorly in low-intensity diffuse light due to significant Shockley-Read-Hall recombination, which is characteristic of indoor lighting. For comparison, the power density of indoor light sources is 60-300 μW cm⁻², approximately three orders of magnitude lower than that of terrestrial outdoor solar light.

Light scattering effects also lead to spectral distortion in favor of higher energy wavelengths, which can exacerbate the problem of spectral mismatch. The combination of these limiting factors results in typical indoor power conversion efficiencies (PCE) of 3-6% with c-Si PV.

Building integrated photovoltaics (BIPV) have a number of limitations when it comes to the harvesting of outdoor light. BIPV can be embedded in façades or windows, allowing them to be transformed into energy harvesting units. In this configuration, the design options for standard PV cells are limited because they are typically black and opaque. Aesthetically, luminescent spectral conversion layers are an appealing solution, as they can be produced in almost any shape and colour (See for example R. A. S. Ferreira et al., Mater. Today, 2020, 33, 105-121.). Moreover, PV panels operate optimally under uniform and direct irradiation, which is not the case for BIPV where sunlight is often diffuse and shaded. Luminescent spectral conversion layers operate similarly under direct and diffuse conditions. They can be applied over large areas and easily incorporated into construction elements. A final challenge arises in tracking systems designed to orient PV towards the sun. These systems work poorly under diffuse light, which is characteristic of cloudy weather conditions.

The present inventors therefore had the idea to pursue a primary objective related to the design and preparation of a polymer film for improving the efficiency of PV cells under indoor and/or diffuse lighting conditions. The project leading to this application has received funding from the European Research Council (ERC) under the European Union's Horizon 2020 research and innovation programme (grant agreement No 818762); the Engineering & Physical Sciences Research Council (reference number EP/V048953/1); and the Isaac Newton Trust (reference number 22.39(m)).

The luminescent polymer film of the present disclosure is thin and is preferably encoded with a patterned array of discreet, cylindrical channel waveguides. The waveguide array of the present invention is preferably formed through the self-trapping of light through a spatially controlled polymerisation process. Furthermore, the present disclosure is also directed to a fabrication process of luminescent polymer film preferably done by injecting a photosensitive sol into a transparent ring cell.

Accordingly, an aspect of the present disclosure, is a method of making a thin luminescent polymer film. The luminescent polymer film is preferably a luminescent waveguide-encoded lattice (LWEL) which is produced by enhancing PV cell performance comprising of three working principles and followed by a fabrication process. The first working principle is self-trapping of light by the polymer host. The second working principle is the luminescence downshifting by the luminophore(s). The third working principle is the patterning of selected waveguide geometries. The combination of the three working principles enables the luminescent waveguide-encoded lattices (LWEL) to both expand the field of view (FoV) and spectrally tune light for the desired application (FIG. 1).

In a specific aspect, provided herein is a process to self-trap the light by the host polymer that has a high refractive index contrast (Δn>0.001; “Δn” here refers to the refractive index contrast between the cylindrical channels and their surroundings. By designing for a higher refractive index channel, and a lower refractive index surroundings, light can be guided down the cylindrical channels by total internal reflection, as demonstrated in optical fiber technologies). In some embodiments, a polymerisation process consists of a photoinitiated process that is spatially controlled to pattern waveguide channels at the micrometer scale. In some embodiments, the polymerisation process consists of photopolymerisation chemistries that are optically transparent and insensitive to phase and amplitude fluctuations at femtosecond (fs) timescales. In some embodiments, the photoinitiator used is a titanocene-based photoinitiator. In another aspect, provided herein is the use of luminescent materials or luminophores for luminescence downshifting. In some embodiments, the luminescent film comprises of an acrylate-epoxy composite and BASF Lumogen F Violet (R) for luminescent downshifting. In another aspect, provided herein is the patterning of certain waveguide geometries.

In another aspect, the fabrication of luminescent polymer films is done by injecting a photosensitive sol into a transparent ring. The photosensitive sol consists of an acrylate with high refractive index contrast and an epoxide component. Waveguide patterning is based on a photopolymerisation process, which requires one or more photoinitiators to drive the polymerisation reaction. For example, a titanocene-based photoinitiator can be used to initiate the polymerisation process of both chemistries—acrylate and epoxides. This photoinitiator absorbs light in the visible range and decays after polymerisation to yield a transparent material.

### SUMMARY

Viewed from a first aspect, the present invention provides a method of fabricating a thin luminescent polymer film, preferably a luminescent waveguide-encoded lattice (LWEL), having a patterned waveguide geometry, the method comprising:
the polymerisation of a photosensitive sol, the polymerisation preferably being characterised by the self-trapping of light,
wherein the sol comprises at least one luminophore suitable for luminescence downshifting.

Viewed from another aspect, the present invention provides a thin luminescent polymer film, preferably an LWEL, obtained or obtainable, preferably obtained, by a method as hereinbefore described.

Viewed from another aspect, the present invention provides a photosensitive sol for the fabrication of a thin luminescent polymer film, preferably a luminescent waveguide-encoded lattice, the sol comprising:
one or more monomers;
at least one photoinitiator; and
at least one luminophore suitable for luminescence downshifting.

Viewed from another aspect, the present invention provides a method of preparing a photosensitive sol as hereinbefore described, the method comprising mixing together:
the one or more monomers;
the at least one photoinitiator; and
the at least one luminophore suitable for luminescence downshifting.

Viewed from another aspect, the present invention provides a method of fabricating a thin luminescent polymer film, the method comprising:
exposing a photosensitive sol as hereinbefore described to light in a selected patterned geometry.

Viewed from another aspect, the present invention provides a thin luminescent polymer film, preferably an LWEL, obtained or obtainable, preferably obtained, by the method as herein before described.

Viewed from another aspect, the present invention provides a thin luminescent polymer film, preferably an LWEL, comprising:
a patterned waveguide geometry; and
at least one luminophore suitable for luminescence downshifting.

Viewed from another aspect, the present invention provides an apparatus comprising:
a photovoltaic (PV) cell; and
a film, preferably an LWEL, as hereinbefore described assembled thereon.

Viewed from another aspect, the present invention provides the use or application of any aforementioned aspect of the present invention to enhance photovoltaic cell performance.

### DESCRIPTION OF THE DRAWINGS

FIG. 1 (a) shows the diagram of an LWEL retrofitted to a PV cell. FOV=field of view. (b) LWEL under white light illumination where left is non-luminescent, and right is luminophore-doped. (c) LWEL under UV (365 nm) irradiation. The film size is 50 mm×50 mm.

FIG. 2 (Left) UV-Vis absorption spectra of a selection of luminophores with the typical emission from white LEDs overlayed. (Right) Fluorescence emission spectra of a selection of luminophores with the external quantum efficiency of a crystalline silicon photovoltaic cell overlayed.

FIG. 3 (Left) UV-Vis absorption spectra of a selection of luminophores with the AM1.5G solar reference spectrum overlayed. (Right) Fluorescence emission spectra of a selection of luminophores with the external quantum efficiency of a crystalline silicon photovoltaic cell overlayed.

FIG. 4 shows the comparison of waveguide angular acceptance ranges in curved and planar surfaces.

FIG. 5 (a) shows the plano-convex lens (L1) used to collimate light incident onto luminescent photopolymerizable material. Amplitude mask (A) with grid pattern (40×40 μm squares, periodicity=80 μm) allows light to enter through optically transparent regions. This allows the photochemical reactions to take place and for the sqLWEL fabrication process to begin. (b) Shows the scheme of slab of waveguides oriented at θwg=0° (denoted as the sqWEL) and their associated FOV.

FIG. 6 (a) shows the simplified fabrication of RD-LWEL film where light is collimated using a plano-convex lens (L1) onto a cylindrical condenser lens (Lc), which focuses light through an amplitude mask (A) with a grid pattern (40×40 km squares, periodicity=80 μm) and onto the luminescent photopolymerisable material. The amplitude mask allows light to enter through optically transparent regions in the mask. This allows the photochemical reactions to take place and for the RD-LWEL fabrication process to begin. (b) Shows the single layer of RD-LWEL geometry with monotonic, radial distribution of waveguides. The panoramic FOV of the RD-LWEL is a result of the sum of angular ranges of each waveguide in the array. (c) shows the 3-D model of the RD-LWEL demonstrating a seamless, panoramic FOV at the exit face of the structure.

FIG. 7 (a) shows the LWEL fabrication setup. From right to left: a collimated white LED source is directed through an aperture and photomask. A cylindrical lens is placed before the photomask and a ring cell containing the polymer sol is placed after the photomask. A lens is used to collimate the transmitted light, with 50% directed towards a CCD camera and 50% directed towards a spectrometer, using a beam splitter cube. (b) shows an example optical micrograph of a fabricated LWEL with 40 μm channels.

FIG. 8 shows the temporal evolution of spatial intensity profiles of the beam at the exit face (pathlength=2 mm) during self-trapping of the acrylate Lumogen Red sqLWEL irradiated at 1.02 mW/cm². Images were acquired at time intervals specified on the image (images acquired using a charged-couple device (CCD) WinCamD digital camera, Data Ray Inc., USA) (scale bar=200 μm).

FIG. 9 shows the sqLWEL 6:4 composite film with Lumogen Violet incorporated as a luminophore. (a) is a micrograph of a fully-formed LWEL film with 40 μm channels. (b) shows the photoluminescence spectrum of Lumogen Violet LWEL with an emission wavelength of 440 nm and an excitation wavelength of 365 nm.

FIG. 10 shows the transmission optical microscopy images of acrylate sqLWEL with Lumogen Red. (scale bar=200 μm).

FIG. 11 shows the plot of normalized integrated intensity versus incidence angle of the probe beam for the acrylate sqWEL (with Lumogen Red) with waveguides oriented at θwg=0°. The angular acceptance range is reported to be 18.0° for this lattice (at 1/e² integrated intensity values).

FIG. 12 shows a scheme of the RD-LWEL with color-coded squares, which were characterized with the Acrylate RD-LWEL with Lumogen Red through transmission optical microscopy (scale bar=200 μm).

FIG. 13 shows a plot of normalized integrated intensity versus incidence angle of the probe beam for the acrylate RD-LWEL (with Lumogen Red) with waveguides oriented at θwg=0.0° and ±13.5°. Note: the yellow circle highlights a corrupt data point. The angular acceptance ranges are reported at 1/e² integrated intensity values.

FIG. 14 shows the current-voltage sweeps performed in reverse (high to low) with an angle-dependent solar simulator (AM1.5G solar standard). Current-voltage sweeps were performed at (a) 20 degrees (b) 15 degrees (c) 10 degrees (d) 5 degrees and (e) normal incidence. (f) shows the irradiance geometry. The ‘Control’ sample is a bare c-Si PV cell. The ‘RDWEL out’ sample was a 1 mm thick radially-distributed lattice incorporating Coumarin 153. The ‘SqWEL’ sample was a 2 mm thick square lattice incorporating Coumarin 153. Both LWELs consisted of a 6:4 acrylate to epoxy composite.

FIG. 15 is a schematic representation of bulk sample and (L)WEL fabrication by photopolymerisation, as discussed in Examples—Section 2. Sol 1 consists of the methacrylate-substituted siloxane precursor, MAPTMS, and HCl (0.05 M). Sol 2 contains the epoxide component system based on p-PDMS and EEC, pTHF (hydrogen donor) and OPPI (co-photoinitiator). The sols are either treated individually or mixed in a 1:1 blend. The photoinitiator (Omnirad™ 784) and luminophore (Lumogen® Violet) are added to the sols before irradiation with white light (halogen or LED). Direct irradiation results in bulk polymer samples, while the presence of a photomask leads to micropatterned (L)WEL samples. For L(WEL) samples, the kinetics upon photoirradiation are followed by in situ UV-Vis absorbance spectroscopy.

FIG. 16 shows UV-Vis absorbance spectra and chemical structures of Omnirad™ 784, OPPI and Lumogen® Violet (LV) in toluene (solid lines). The fluorescence spectrum of LV (λ_{exc}=375 nm) is superimposed for comparison (dashed line).

FIG. 17 shows initial rate analysis of photoinitiator consumption during photopolymerization of bulk Acr-Sil, Epo and Blend 1:1 sols, as discussed in Examples—Section 2. The molar consumption of Omnirad™ 784 with time under halogen lamp irradiation (0.63 mW cm⁻²) was monitored by UV-Vis absorbance spectroscopy for sols (a) without LV and (b) with LV (0.02 wt %). The grey shaded regions (0-150 s) indicate the linear region where an initial rate fit to a pseudo-zero order rate equation was performed (insets).

FIG. 18 shows the effect of photoinitiators on the fluorescence decay kinetics of LV in toluene (λ_{exc}=375 nm, λₑₘ=430 nm), as discussed in Examples—Section 2. (a) Low concentration (5 μM LV) decay curves showing no quenching effect upon the addition of Omnirad™ 784 (200 μM) or OPPI (550 μM). (b) High concentration (300 μM LV) photoluminescence decay curves showing a decrease in lifetime upon the addition of OPPI (30 mM), Omnirad™ 784 (10 mM), and photoinitiators simultaneously (10 mM and 30 mM). The solid lines show a single exponential fit to the decay curves. The goodness of fit is demonstrated by the residuals in the bottom panel.

FIG. 19 shows in-situ monitoring of LWEL formation by UV-Vis spectroscopy, as discussed in Examples—Section 2. (a) Micrograph of LWEL film (Blend 3:2) with 40 μm channels and LV incorporated as a luminophore. In-situ spectral map of Blend 3:2 (b) without LV and (c) with LV as polymerization proceeds. The depletion of Omnirad™ 784 is evident in (b,c) from the negative ΔOD at early times (<200 s) below λ=500 nm. Scattering dominates the change in transmission at later times (>200 s), manifesting as an increase in ΔOD across the entire wavelength range (480 nm to 580 nm).

FIG. 20 shows use of photobleaching to eliminate unused photoinitiator in LWELs (3:2 blend). (a) UV-Vis absorbance spectra of LWELs pre- and post-bleach, with LV as the luminophore. (b) Corresponding excitation (lₑₘ=440 nm) and emission (l_{exc}=365 nm) spectra of an LWEL sample.

FIG. 21 shows a schematic of the LWEL fabrication and characterization set-up, as discussed in Examples—Section 2. Transmitted light through the LWEL sample can simultaneously be analyzed by a camera and its spectrum by a spectrometer to monitor changes in absorbance in situ.

FIG. 22 is a photograph of an epoxide WEL sample fabricated using Omnirad™ 784 (0.05 g) as the photoinitiator, with OPPI as the co-initiator, under irradiation for 12 minutes (irradiance=1.5 mW cm⁻², white LED Thorlabs MCWLH7). The longest side is 2.5 cm in length. The epoxide sol consisted of EEC (2.54 g), pPDMS (1.31 g), pTHF (1.00 g), OPPI (0.10 g) and Omnirad™ 784 (0.05 g).

FIG. 23 shows emission spectra of the two light sources used for photopolymerization: MRL-58 halogen lamp (bulk samples) and Thorlabs MCWLH7 white LED (LWELs). Spectra were obtained using a calibrated NIST-traceable ILT950 spectroradiometer with W2 wide-eye diffuser. The integrated irradiance in the visible region (380-780 nm) was 0.63 mW cm⁻² for the cool white halogen source and 1.4 mW cm⁻² for the white LED. The background lab lighting irradiance was 0.05 mW cm².

FIG. 24 shows (a) plot of the raw absorbance data of an Acr-Sil (LV) sol during photolysis of Omnirad™ 784 showing a clear scattering artefact above 550 nm. (b) Plot of the data corrected for scattering by subtracting the average absorbance in the wavelength range 575 nm to 600 nm from all data points in (a).

FIG. 25 shows (a) UV-Vis absorbance spectra of polymer sols with and without Omnirad™ 784. Absorbance values were averaged in the wavelength range 450 nm to 455 nm then converted to an absorbance coefficient in (b). Omnirad™ 784 concentration in acrylate (Acr-Sil) sol was 10 mM, epoxide (Epo) sol was 4 mM, and blend sol was 7 mM. The path length was 2 mm. The absorbance coefficients of Omnirad™ 784 in each sol were calculated to be: Acr-Sil 711 M⁻¹ cm⁻¹, Epo 1,213 M⁻¹ cm⁻¹ and Blend 893 M⁻¹ cm⁻¹.

FIG. 26 shows first-order kinetic decay plot of the photolysis of Omnirad™ 784 present at low concentration (1 mM) in Acr-Sil sols upon irradiation with a halogen lamp, showing a linear relationship between [Omnirad] and time.

FIG. 27 shows comparison of the CAM-B3LYP, B3LYP and experimental absorbance spectra of a) Omnirad™ 784 and b) Lumogen Violet®, with the B3LYP functional showing a better overlap with the experimental results.

FIG. 28 shows a diagram of the HOMO-LUMO energies of Omnirad™ 784, OPPI and LV showing the potential electron transfer reactions, and the favored route via an excited state LV.

FIG. 29 shows photoluminescence decay curves (open symbols) and corresponding fits (solid lines) to a bi-exponential decay function for LV-LWEL (blend 3:2) pre- (black) and post-bleaching (red) of unconsumed Omnirad™ 784 photoinitiator. Excitation wavelength=375 nm. Emission wavelength=430 nm.

### DEFINITIONS

In understanding the scope of the present disclosure, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. The term “consisting” and its derivatives, as used herein, are intended to be closed terms that specify the presence of the stated features, elements, components, groups, integers, and/or steps, but exclude the presence of other unstated features, elements, components, groups, integers and/or steps. The term “consisting essentially of”, as used herein, is intended to specify the presence of the stated features, elements, components, groups, integers, and/or steps as well as those that do not materially affect the basic and novel characteristic(s) of features, elements, components, groups, integers, and/or steps.

Terms of degree such as “substantially”, “about” and “approximately” as used herein mean a reasonable amount of deviation of the modified term such that the end result is not significantly changed. These terms of degree should be construed as including a deviation of at least ±5% of the modified term if this deviation would not negate the meaning of the word it modifies. In addition, all ranges given herein include the end of the ranges and also any intermediate range points, whether explicitly stated or not.

As used in this disclosure, the singular forms “a”, “an” and “the” include plural references unless the content clearly dictates otherwise.

In embodiments comprising an “additional” or “second” component, the second component as used herein is chemically different from the other components or first component. A “third” component is different from the other, first, and second components, and further enumerated or “additional” components are similarly different.

The term “and/or” as used herein means that the listed items are present, or used, individually or in combination. In effect, this term means that “at least one of” or “one or more” of the listed items is used or present.

The abbreviation, “e.g.” is derived from the Latin exempli gratia and is used herein to indicate a non-limiting example. Thus, the abbreviation “e.g.” is synonymous with the term “for example.” The word “or” is intended to include “and” unless the context clearly indicates otherwise.

The term “EEC” as used herein refers to 3,4-epoxycyclohexylmethyl 3,4-epoxycyclohexanecarboxylate.

The term “pPDMS” as used herein refers to epoxypropoxypropyl-terminated polydimethylsiloxane.

The term “MAPTMS” as used herein refers to 3-(trimethoxysilyl)propyl methacrylate.

The term “lumophore” as used herein is entirely interchangeable with the term “luminophore”, and vice versa.

It will be understood that any component defined herein as being included may be explicitly excluded by way of proviso or negative limitation, such as any specific compounds or method steps, whether implicitly or explicitly defined herein.

### DETAILED DESCRIPTION

The present invention provides a method of fabricating a thin luminescent polymer film, preferably a luminescent waveguide-encoded lattice (LWEL), having a patterned waveguide geometry, the method comprising:
the polymerisation of a photosensitive sol, the polymerisation preferably being characterised by the self-trapping of light,
wherein the sol comprises at least one luminophore suitable for luminescence downshifting.

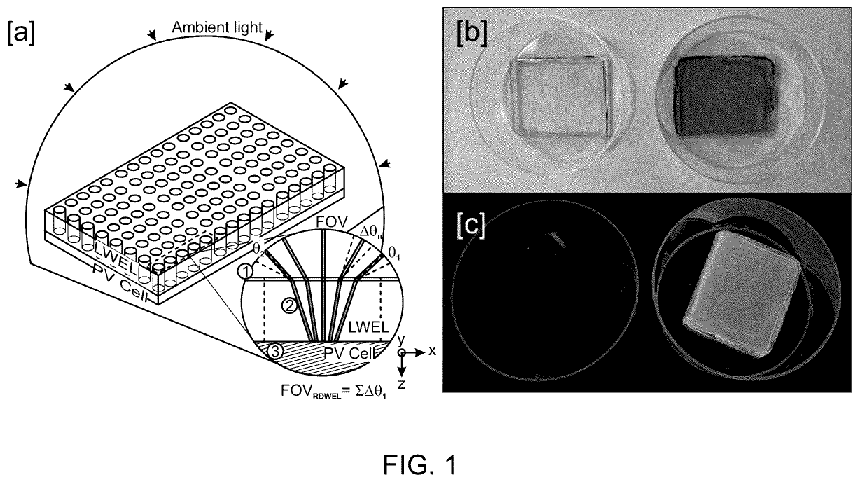

The method of the present invention enables the production of thin luminescent polymer films, which may preferably be LWELs. The method of the present invention makes use of three working principles. The first working principle is self-trapping of light by the polymer host. The second working principle is the luminescence downshifting by the luminophore(s). The third working principle is the patterning of selected waveguide geometries. The combination of the three working principles enables the luminescent waveguide-encoded lattices (LWEL) to both expand the field of view (FoV) and spectrally tune light for the desired application (FIG. 1). For example, one potential application of the present invention is related to the design and preparation of a luminescent polymer film for improving the efficiency of PV cells under diffuse and/or indoor lighting conditions.

To pattern waveguide channels at the micrometer scale, there is a requirement for a fabrication process that can be spatially controlled. A photoinitiated polymerisation process enables this to occur. In such a case, the polymer host can be fabricated from the selective exposure of its precursor—a photosensitive sol—to light in pre-defined regions, in order to exert control over the seeding of waveguide formation. This can, for example, be achieved using masks that block light in pre-defined regions—similar to those employed in lithographic techniques. However, unlike lithographic techniques, the fabrication processes described herein can occur at room temperature and create complex waveguide structures not seen typically with lithography.

Crucially, the light beams must self-trap as the waveguides are seeded, in order to enable the propagation of light within the nascent channels, leading to the formation of the waveguide-encoded lattice. When a light beam self-traps, it induces a narrow waveguide through which it propagates without diffracting (broadening). Accordingly, one working principle of the method of the present invention is the self-trapping of light. The polymerisation is thus preferably characterised by the self-trapping of light.

Self-trapping can be controlled by the choice of monomers, the choice of polymerisation mechanism, the intensity of light, and the wavelength of the light. Waveguide channels only form when light is self-trapped. The self-trapping effect can be observed by microscopy. The light beams induce channel formation without diffracting (broadening) so well-defined spots can be seen through the microscope, as described in the Examples.

The method of the present invention thus comprises a fabrication process comprising the polymerisation of a photosensitive sol. It will be understood that a polymer host is derived from polymerisation of the photosensitive sol. Such a polymerisation process may preferably be initiated by light. The propagation of such a polymerisation may be characterised by the self-trapping of light by the polymer host, i.e. by the nascent polymer host, which is derived from polymerisation of the sol.

Said another way, the polymerisation can be characterised by formation of a polymer host, and the polymerisation can be propagated by self-trapping of light by the polymer host, i.e. by the nascent polymer host. The polymer host provides the medium in which the waveguide lattice in encoded.

The fabrication process preferably comprises placing, e.g. injecting, the sol into a container for exposure to light. Such a container is preferably transparent and/or is preferably configured to provide a desired film thickness. The exact dimensions of the container may therefore depend on the volume of sol to be used and the desired thickness of the final film. Preferred thicknesses are less than 5 mm, more preferably less than 2 mm, e.g. about 1 mm or less. A preferred type of container is a ring cell. Accordingly, the fabrication process of the luminescent polymer film is preferably done by injecting a photosensitive sol into a transparent ring cell.

Preferably, the fabrication process comprises exposing the photosensitive sol to light. This preferably initiates polymerisation of the sol. Preferably, the sol is exposed to light in a selected patterned geometry. Preferred geometries, and means for achieving this patterning, are discussed in more detail below.

The polymerisation of the sol is preferably initiated by a photoinitiator. It will be understood that a photoinitiator is a species suitable for initiating polymerisation by absorbing light in the spectrum of incident light. Incident light can be incident natural light, e.g. sunlight, and/or incident artificial light, e.g. LED light, preferably white LED light. The exact type of photoinitiator need not be particularly limited, and certain examples will be known to those skilled in the art. It is preferred that the photoinitiator is suitable for initiating polymerisation by absorbing light in the visible range.

Accordingly, the photosensitive sol preferably comprises a photoinitiator. The photoinitiator may thus be responsible for the photosensitivity of the sol. Said another way, the photosensitive sol preferably comprises a photoinitiator and the polymerisation of the sol is preferably initiated by the photoinitiator.

It is preferred that the photoinitiator decays to yield a transparent material. In other words, the photoinitiator should preferably be, or should preferably decay to yield a product which is, transparent in the visible region. This desirably minimises losses due to parasitic absorption, maximising the performance of the device for light harvesting applications, e.g. for use with an adjacent or underlying cell, such as a PV cell. It has been found that bis(f-cyclopentandienyl) bis(2,6-difluoro-3-(1H-pyrrol-yl)-phenyl) titanium(IV) advantageously exhibits desirable levels of visible light absorbance, enabling good levels of LWEL formation, while also decaying to yield a transparent material, minimising parasitic absorption of light.

Preferably, the photoinitiator is a transition-metal-based photoinitiator, preferably a titanium-based photo-initiator. Preferably, the photo-initiator is a metallocene-based photoinitiator, preferably a titanocene-based photoinitiator. Most preferably, the photoinitiator is bis(f-cyclopentandienyl) bis(2,6-difluoro-3-(1H-pyrrol-yl)-phenyl) titanium(IV).

In some methods, the type of polymerisation need not be particularly limited. However, it is preferred that the polymerisation is a cationic polymerisation, a free radical polymerisation, or a combination of the two. The type of photoinitiator may be chosen accordingly. A co-initiator may also be used. In the case of cationic polymerisations, preferred monomers are monomers comprising at least one polymerisable functional group selected from epoxide, vinyl ether, lactone, acetal, cyclic ether, and oxetane. In the case of free radical polymerisations, preferred monomers are acrylate, preferably methacrylate, monomers. As one non-limiting example, the polymerisation may comprise the free radical polymerisation of an acrylate monomer, and the cationic polymerisation of an epoxide monomer.

Preferably, the method comprises a step of irradiating with light. Preferably, this step occurs after polymerisation. The light is preferably white light, e.g. white LED light. This is preferably done to degrade the photoinitiator. This is preferably done in conjunction with a long pass filter, which is preferably configured to prevent passage of light having a wavelength having light of less than 520 nm, more preferably less 500 nm, still more preferably less than 495 nm, in order to prevent luminophore photodegradation. The irradiation is preferably of the whole polymer host or film. It has been found that such a step leads to fluorescence enhancement.

The photosensitive sol preferably comprises one or more monomers, i.e. one or more types of monomers. The polymerisation, which is preferably photoinitiated, of the monomers drives the formation of the polymer host, in which the waveguide lattice is encoded. The nature of the monomers need not be particularly limited, and the skilled person will be aware of certain examples which are suitable for use in the fabrication of waveguide-encoded lattices. Preferred monomers include monomers having at least one polymerisable functional group selected from epoxide, vinyl ether, lactone, acetal, cyclic ether, oxetane, and acrylate, preferably methacrylate.

The one or more monomers preferably includes acrylate monomers and/or epoxide monomers. The one or more monomers preferably comprises organosiloxane monomers, preferably wherein the siloxane is a polysiloxane, preferred organo groups being acrylate-containing or epoxide-containing groups. Said another way, the one or more monomers preferably comprises monomers having —Si—O—, more preferably —O—Si—O— groups.

The sol preferably comprises epoxide monomers and acrylate monomers in a volume ratio of between 5:1 to 1:5, more preferably 3:1 to 1:3, still more preferably 3:2 to 2:3, yet more preferably about 1:1. Alternatively, or in addition, the sol preferably comprises epoxide monomers and acrylate monomers in a wt ratio of between 5:1 to 1:5, more preferably 3:1 to 1:3, still more preferably 3:2 to 2:3, yet more preferably about 1:1

Preferably, the one or more monomers comprises one or more types of acrylate monomers.

Preferred acrylate monomers are methacrylate monomers. Preferred acrylate monomers comprise the following group:

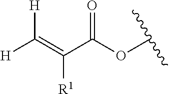

wherein R¹ is H or alkyl, preferably C1-C8 alkyl, more preferably methyl; and
the wavy line denotes a link to another chemical functionality, the identity of which is not intended to be particularly limited.

Preferred acrylate monomers are acrylate-siloxane monomers. It will be understood that such a monomer comprises at least one polymerisable acrylate group, in addition to a siloxane functionality. The one or more monomers may comprise an ingredient which is a polysiloxane with free polymerisable acrylate functional groups. A preferred example is a polysiloxane derived from polymerisation of MAPTMS, e.g. by acid catalysis, having free polymerisable acrylate groups.

Preferred acrylate monomers have the following formula:

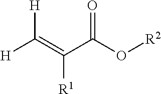

wherein R¹ is alkyl, preferably C1-C8 alkyl, more preferably methyl; and
R² is a siloxane-containing group, preferably a polysiloxane-containing group.

It is particularly preferred that the one or more monomers comprises an ingredient having a unit of the following formula:

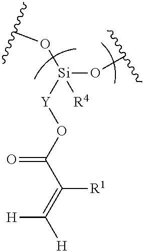

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group; and
R⁴ is H, OH, or an alkyl or an alkoxy group, preferably a C1-C8 alkyl or C1-C8 alkoxy group, more preferably a C1-C2 alkyl or C1-C2 alkoxy group.

Wavy lines denote a point of attachment to other chemical groups, e.g. end groups, a repeat of the unit, or a different unit.

It will be understood that polymerisation can proceed via polymerisation of the acrylate groups, in order to form the polymer host.

It is particularly preferred that R¹ is methyl, Y is propylene, and R⁴ is methyl or a point of attachment to another repeating group. Such a repeating unit can be derived from the polymerisation of MAPTMS using an acid catalyst, e.g. HCl.

Such an ingredient may alternatively or additionally have a unit of the following formula:

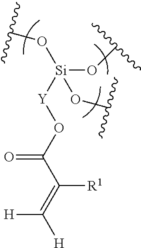

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group; and
R⁴ is H, OH, or an alkyl or an alkoxy group, preferably a C1-C8 alkyl or C1-C8 alkoxy group, more preferably a C1-C2 alkyl or C1-C2 alkoxy group;
Wavy lines denote a point of attachment to other chemical groups, e.g. end groups, a repeat of the unit, or a different unit.

Such a repeat unit is understood to be tri-functional, leading to branching.

It is particularly preferred that the one or more monomers comprises a polymer structure having the following formula:

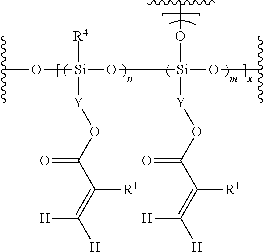

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and R¹, R⁴, and Y may at each occurrence be the same or different, preferably the same.

Wavy lines denote a point of attachment to other chemical groups, e.g. end groups.

n and m are independently selected as a fraction from 0 to 1, where n+m=1. n therefore represents the proportion units of the type bound by ( )ₙ in the overall polymer structure. Similarly, m represents the proportion of units of the type bound by ( )ₘ in the overall polymer structure. The overall polymer structure has a total degree of polymerization x. The number of units of the type bound by [ ]ₙ in the overall polymer structure is represented by the product of x and n, the product preferably being an integer. The number of units of the type bound by [ ]ₘ in the overall polymer structure is represented by the product of x and m, the product preferably being an integer. It will be understood that each of the two types of repeating unit may be distributed randomly throughout the overall structure. A unit of the type bound by n may therefore be adjacent in one direction of the polymer chain to a unit of the same type, or a unit of the type bound by m.

The ratio of the values of n:m may be between 100:0 to 0:100. Preferably, the ratio of the values of n:m is 50:50 to 99:1, preferably 60:40 to 90:10, more preferably 65:35 to 85:15. Preferably, the ratio of the values of m:n is 50:50 to 99:1, preferably 60:40 to 90:10, more preferably 65:35 to 85:15. Preferably, the ratio of the values of n:m is 80:20 to 20:80, preferably 70:30 to 30:70, more preferably 60:40 to 40:60.

It is particularly preferred that the one or more monomers comprises an ingredient having the following formula:

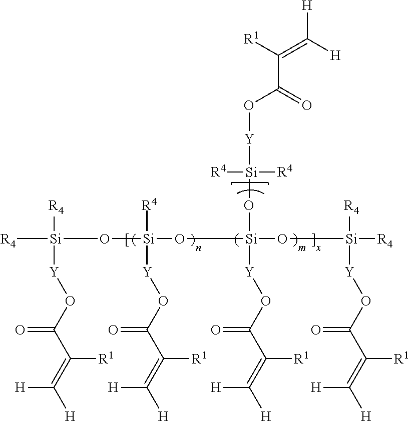

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group; and
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25.
R1, R⁴, Y, may at each occurrence be the same or different, preferably the same.

As described above, n and m are independently selected as a fraction from 0 to 1, where n+m=1.

Preferably, the photosensitive sol comprises one or more types of epoxide monomers. Preferably, epoxide monomers have a plurality, e.g. 2, epoxide groups. Preferred epoxide monomers are epoxide-siloxane monomers. It will be understood that such a monomer comprises at least one polymerisable epoxide group, in addition to a siloxane group, preferably a polysiloxane group. A preferred example of this is p-PDMS.

Preferred epoxide monomers have the following formula:

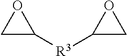

wherein R³ is a linking group, which may be substituted or unsubstituted, branched or unbranched, and which may optionally contain one or more heteroatoms.

R³ preferably comprises a group of the following formula:

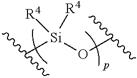

more preferably a group of the following formula:

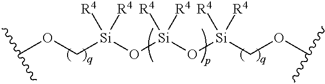

wherein
R⁴ denotes H, OH, or an alkyl or an alkoxy group, preferably a C1-C8 alkyl or C1-C8 alkoxy group, more preferably a C1-C2 alkyl or C1-C2 alkoxy group;
p is an integer from 0-50, preferably 0-20, more preferably 1-10, still more preferably 20
q is an integer from 0 to 12, preferably 2 to 8, still more preferably 3 to 5.
wavy lines denote a point of attachment to other chemical groups, or—if R³ consists of the above formulae—a point of attachment to the depicted epoxide groups.

Preferably, R³ consists of:

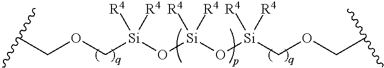

wherein
R⁴ denotes H, OH, or an alkyl or an alkoxy group, preferably a C1-C8 alkyl or C1-C8 alkoxy group, more preferably a C1-C2 alkyl or C1-C2 alkoxy group;
p is an integer from 0-50, preferably 0-20, more preferably 1-10, still more preferably 20; and
q is an integer from 1 to 12, preferably 2 to 8, still more preferably 3 to 5.

Particularly preferred epoxide monomers include p-PDMS and EEC.

Preferably, the one or more monomers comprises at least one type of epoxide monomer, preferably an epoxide-siloxane monomer, more preferably an epoxide-polysiloxane monomer, and at least one type of acrylate monomer, preferably an acrylate-siloxane monomer, more preferably an acrylate-siloxane monomer. Preferably, the wt ratio of epoxide monomers to acrylate monomers is between 5:1 to 1:5, more preferably 3:1 to 1:3, still more preferably 3:2 to 2:3, yet more preferably about 1:1.

It is preferred that the one or more monomers comprise organosiloxane monomers, preferably wherein the siloxane is a polysiloxane. This component is thought to improve the mechanical properties of the polymer. It will be understood that the organo group preferably contributes the polymerisable groups. Preferred organo groups are acrylate-containing, preferably methacrylate-containing, and epoxide-containing groups.

Preferably, the sol comprises:
an acrylate monomer, preferably an acrylate-siloxane monomer, more preferably wherein the siloxane is a polysiloxane;
a first epoxide monomer, preferably an epoxide-siloxane monomer, more preferably wherein the siloxane is a polysiloxane
a second epoxide monomer.

It has been found that the combination of an epoxide monomer and an acrylate monomer leads to improved mechanical properties, such as reduced brittleness, e.g. as compared with the use of an acrylate monomer alone. It is thought that the use of an acrylate monomer, which is preferably an acrylate-siloxane monomer, more preferably wherein the siloxane is a polysiloxane, results in good Δn, as defined herein. It is also thought that the presence of Si—O bonds, afforded by the presence of an organosiloxane component, offers refractive index close to glass to minimise losses to reflection. Such bonds are also advantageously transparent in the visible region.

For example, it is particularly preferred that the one or more monomers comprises:
a polysiloxane derived from polymerisation of MAPTMS, having free polymerisable acrylate groups
p-PDMS; and
EEC.

It is also particularly preferred that the one or more monomers comprises:
p-PDMS;
EEC; and
an ingredient comprising a polymer structure having the following formula:

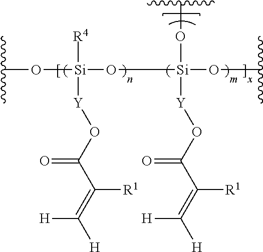

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and
R¹, R⁴, and Y may at each occurrence be the same or different, preferably the same.

It is preferred that the sol comprises the luminophore, the preferred features of which are discussed in more detail below.

Overall, it is preferred that the photosensitive sol comprises:
one or more monomers;
at least one photoinitiator; and
at least one luminophore suitable for luminescence downshifting.

The sol may comprise other ingredients and additives. Examples include solvents, hydrogen donors, and co-initiators.

The fabrication process preferably comprises a preliminary step of preparing the photosensitive sol. Such a step preferably comprises mixing together:
the one or more monomers;
the at least one photoinitiator; and
the at least one luminophore suitable for luminescence downshifting.

The fabrication process may comprise preliminary steps of:
preparing a first sol;
preparing a second sol; and
combining the first and second sols to give the photosensitive sol.

It is preferred that at least one of the first and second sol comprises at least one photoinitiator. It is also preferred that at least one of the first and second sol comprises the least one luminophore suitable for luminescence downshifting. Alternatively, a photoinitiator and luminophore can be added separately.

Preparing at least one of the first or second sol preferably comprises preparing a polysiloxane. This may be achieved by mixing a polymerisation catalyst, preferably an acid, more preferably hydrochloric acid, with one or more monomers comprising a group suitable for the formation of a polysiloxane, a preferred example of which is MAPTMS. Preferably, such a preparation retains chemical groups suitable for polymerisation in the fabrication of the film, preferably acrylate groups. Such a preparation enables control over the sol viscosity and allows tuning of the kinetics of the photopolymerisation process. It is preferred that the polysiloxane comprises a polymer structure having the following formula:

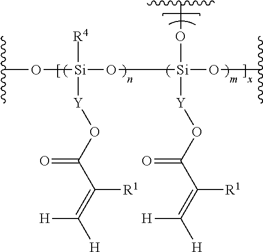

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and
R¹, R⁴, and Y may at each occurrence be the same or different, preferably the same.

Preferably at least one of the first and second sol comprises acrylate monomers, preferably acrylate-siloxane monomers, more preferably acrylate-polysiloxane monomers. Preferably at least one of the first and second sol one or more, preferably two, epoxide monomers, preferably epoxide-siloxane monomers, more preferably epoxide-polysiloxane monomers.

The polymerisation of the method of the present invention yields a polymer host, fabricated from the photosensitive sol. A purpose of the polymer host is to provide the medium of which the LWEL is formed. As discussed previously, the self-trapping of light by the polymer host contributes to the formation of the waveguide-enclosed lattice. Preferred features and examples of the polymer host are discussed below. The nature of the polymer host need not be particularly limited, and the skilled person will be aware of certain examples which are suitable for use in the formation of waveguide-encoded lattices. It will be understood that the nature of the polymer host and the photosensitive sol are closely linked, the former being derived from polymerisation of components of the latter.

As used herein, the term “refractive index contrast (Δn)” refers to the difference in refractive index between a waveguide channel and its surrounding matrix. It can be measured by methods known in the art, or by consulting tabulated values. One way of calculating the refractive index contrast is by using:

nₐᵢᵣ sin(θ)=(n_{core}²−n_{clad}²)^{1/2}

where nₐᵢᵣ is the refractive index of air, n_{core} is the refractive index of the channels, n_{clad} is the refractive index of the channel surroundings, and θ is the angular acceptance cone of a waveguide.

For the more effective angular collection of light by each waveguide channel, a high refractive index contrast is preferred between the channel and the surrounding matrix. The polymer host therefore preferably provides a refractive index contrast (Δn) of greater than 0.001, more preferably greater than 0.0025, still more preferably greater than 0.005.

As an example, acrylate chemistries possess high refractive index contrast, with Δn>0.001. Preferably, the polymer host comprises an acrylate component. Such a component may be derived from the polymerisation of an acrylate monomer in a sol as hereinbefore described.

Preferably, the film has a field of view of greater than 10 degrees, more preferably greater than 15 degrees, still more preferably greater than 18 degrees, yet more preferably greater than 25 degrees, greater than 35 degrees, or greater than 40 degrees. The field of view can be determined according to the protocol explained in the Examples.

To better facilitate self-trapping of light, it is preferred that the polymer host is optically transparent.

It is also preferred that the photopolymerisation chemistry is insensitive to phase and amplitude fluctuations at femtosecond (fs) timescales, which are typically seen in incoherent sources such as LEDs. By way of example, the slow evolution of organosiloxane and epoxide polymerisation (ms to minutes) renders the system insensitive to fs fluctuations. They only respond to the time-averaged optical field, which advantageously allows a LED beam to self-trap. Preferably, the polymer host comprises an organosiloxane component, preferably a polyorganosiloxane component. Preferred organo groups are epoxide-containing or acrylate-containing groups. Preferably, the polymer host comprises an epoxide component, preferably an epoxide-siloxane component, more preferably an epoxide-polysiloxane, and/or an acrylate component, preferably an acrylate-siloxane component, more preferably an acrylate-polysiloxane component.

It has been found that composite sols comprising both acrylate and epoxide monomers maintained good formation of cylindrical waveguide channels, along with improved the thermomechanical robustness of the polymer films: the use of acrylate monomers alone was found to lead to high brittleness. Preferably, the polymer host comprises an acrylate component and an epoxide component. In other words, the polymer host is preferably an acrylate-epoxide composite. Preferably, the volume ratio of the epoxide component to the acrylate component is between 5:1 to 1:5, more preferably 3:1 to 1:3, still more preferably 3:2 to 2:3, yet more preferably about 1:1. Preferably, the wt ratio of the epoxide component to the acrylate component is between 5:1 to 1:5, more preferably 3:1 to 1:3, still more preferably 3:2 to 2:3, yet more preferably about 1:1. Such components may be derived from the polymerisation of acrylate monomers and epoxide monomers in a sol as hereinbefore described.

Another working principle of the method of the present invention is the use of at least one luminophore suitable for luminescence downshifting. Such a luminophore is defined herein as being suitable for absorbing incident light at certain wavelengths and emitting light at different wavelengths. Luminophores can advantageously be used to obtain spectral tuning to an adjacent cell. The exact identity of the luminophore need not be particularly limited, and certain examples will be known to the skilled person, which may be suitable for different applications. Preferred features and examples of the luminophore are discussed below.

It is preferred that the luminophore absorbs incident light (high absorption coefficient) at wavelengths where an intended adjacent cell, e.g. PV cell, has poor quantum efficiency. This means that the LWEL can advantageously harvest light at wavelengths the cell cannot. The exact wavelengths of interest will therefore differ depending on the exact nature of the cell. However, the luminophore preferably has an absorbance peak in the range of 300 to 700 nm, more preferably 325 to 600 nm, still more preferably 350 to 550 nm, yet more preferably 400 to 550 nm, still more preferably 450 to 550 nm. Such values may be optimized for a c-Si PV cell.

It is preferred that the luminophore has high transmittance, which is important to avoid parasitic absorption and to convey light to the underlying cell, e.g. PV cell. The luminophore preferably has a transmittance of greater than 90%, more preferably greater than 95%, still more preferably greater than 98%, yet more preferably greater than 99%, e.g. about 100% at wavelengths of interest. Wavelengths of interest are understood to be those at which the luminophore does not absorb, as well as those at which an underlying cell, e.g. PV cell, has good absorbance efficiency. Preferred wavelengths for the aforementioned transmittance values are greater than 500 nm, e.g. greater than 550 nm. Other preferred wavelengths are those given in the immediately preceding and immediately succeeding paragraphs.

It is preferred that the luminophore emits fluorescence at wavelengths where an intended adjacent cell, e.g. PV cell, has good quantum efficiency. This means that the LWEL can advantageously spectrally tune light to match the optimum performance range of the adjacent cell. Accordingly, the luminophore preferably has an emission peak at greater than 400 nm, preferably greater than 420 nm, still more preferably greater than 450 nm, yet more preferably greater than 475 nm, yet more preferably greater than 500 nm, e.g. greater than 550 nm. Preferably, any such peak occurs at a wavelength of less than 750 nm, preferably less than 700 nm, yet more preferably less than 650 nm. Preferred ranges are therefore between 400 to 750 nm, more preferably 450 to 700 nm, still more preferably 500 to 650 nm, e.g. 550 to 650 nm. Such values may be optimized for a c-Si PV cell.

It is also preferred that the luminophore has a high photoluminescence quantum yield (PLQY) and long-term thermal stability and photostability.

Preferably, the luminophore is selected from the group consisting of polymeric or molecular conjugated organic materials such as perylene, coumarin, naphthalimide, poly(fluorene), or benzothiadazole derivatives. More preferably, the luminophore is selected from perylene diimides, e.g. Lumogen Red or Lumogen Orange, 7-amino coumarins, e.g. Coumarin 153, napthalimides, e.g. Lumogen Violet, and poly(fluorene)s, e.g., Lumogen Yellow. Still more preferably, the luminophore is selected from:
2-(2-ethylhexyl)-6,7-dimethoxy-1H-benzo[de]isoquinoline-1,3(2H)-dione (commercial name: Lumogen Violet)
N,N′-bis(2,6-di-tert-butylphenyl)perylene-3,4,9,10-bis(dicarboximide) (commercial name: Lumogen Orange)
9-(Trifluoromethyl)-2,3,6,7-tetrahydro-1H,5H,11H-pyrano[2,3-f]pyrido[3,2,1-ij]quinolin-11-one (commercial name: Coumarin 153)
N,N′-bis(2,6-diisopropylphenyl)-1,6,7,12-tetraphenoxyperylene-3,4:9,10-tetracarboxdiimide (commercial name: Lumogen Red)
3,9-bis(2-methylpropyl) 4,10-dicyanoperylene-3,9-dicarboxylate (commercial name: Lumogen Yellow)
Poly(9,9-dioctylfluorene-alt-benzothiadiazole) (commercial name: F8BT)

It is particularly preferred that the Lumogen is 2-(2-ethylhexyl)-6,7-dimethoxy-1H-benzo[de]isoquinoline-1,3(2H)-dione (commercial name: Lumogen Violet) or N,N′-bis(2,6-di-tert-butylphenyl)perylene-3,4,9,10-bis(dicarboximide) (commercial name: Lumogen Orange) or 3,9-bis(2-methylpropyl) 4,10-dicyanoperylene-3,9-dicarboxylate (commercial name: Lumogen Yellow), more preferably 3,9-bis(2-methylpropyl) 4,10-dicyanoperylene-3,9-dicarboxylate (commercial name: Lumogen Yellow). Lumogen Yellow is well placed for indoor spectral tuning as the absorption of Lumogen Yellow overlaps well with the first peak in the white LED spectrum, and the emission of Lumogen Yellow overlaps well with a higher external quantum efficiency range of silicon PV.

It is preferred that the luminophore is comprised within the polymer host. In other words, preferably the polymer host comprises the luminophore. By combining the use of a luminophore suitable for luminescence downshifting within a waveguide-encoded lattice, the LWEL produced by the method of the present invention advantageously both expands the field of view (FoV) and spectrally tunes light for the desired application.

Preferably, the method of the resent invention comprises the use of dyes with a determinable, e.g. large, Stokes shift, which may enable the performance of the film to be maximized by the minimisation of reabsorption losses. Preferred Stokes shifts are greater than 15 nm, more preferably greater than 20 nm, still more preferably greater than 30 nm, e.g. greater than or equal to about 35 nm. Lumogen Red and Lumogen Violet are preferred examples. Preferably, these dyes are either incorporated into the waveguide structure as part of the bulk material or placed onto a surface of the material; hence good host compatibility is also desirable to minimize optical losses. In other words, a sol as hereinbefore described may comprise such a dye. Alternatively, the dye may be placed onto the film after fabrication.

Another working principle of the method of the present invention is patterning with a selected waveguide geometry. Preferred geometries are square or radial geometries. Waveguide encoded lattices (WELs) are planar optical films inscribed with arrays of cylindrical waveguides. LWELs are fabricated from photosensitive luminescent material that results in freestanding films with spectral tuning properties. Owing to waveguide theory, the refractive index contrast between the core and surrounding (cladding) of dielectric material results in a specific angular acceptance range in which a waveguide can collect and guide light. Therefore, light incident within this angular acceptance range will be collected and confined within the waveguide due to total internal reflection (TIR).

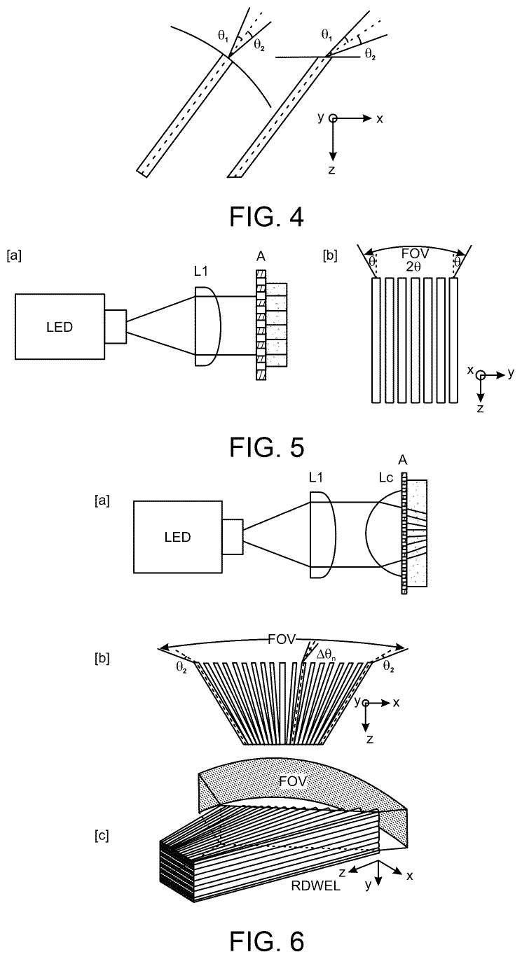

The planar geometry of the LWELs films yields larger FOV as compared to their curved counterparts (FIG. 4). In a curved construct, the waveguide angle (θwg) will always align perpendicularly to a normal along the curved surface. This results in a symmetrically distributed angular acceptance range about θwg; θwg−θ1 and θwg+θ2. In a planar construct, the situation differs. The normal will remain constant along the z-axis in a planar configuration, and so for non-zero θwg the angular acceptance range must account for the refraction of light into the waveguide entrance face. This results in an angular acceptance range that spans about this refraction (θrwg, where θrwg=arcsin[n sin[θwg]]) and results in a larger angular acceptance range (as θwg>0, |θrwg|>|θwg|) and larger FoV as a result (See more for example Lin, H et al., Adv. Optical Mater. 2019, 7, 1801091).

In a theoretical test case scenario for a planar construct with Δn=0.006 and radial waveguide span θwg=±21°, the angular collection range would span from θ1=23.7° to 62=40.6°. In the planar construct scenario, the FOV is determined by the most oblique waveguides (i.e., ±21°) and thus the theoretical FOV is calculated to be ~80° (based on 62=40.6°).

Preferably, the film is therefore a planar film, more preferably a planar LWEL.

The geometry can be a square geometry. Collimating the input beam onto the entrance face of the luminescent photopolymerisable material results in periodic stacks of cylindrical waveguides forming along the beam propagation path, z (FIG. 5). This results in θwg=0°, as there is no focus along the beam path to tilt the waveguides during the inscription process. The theoretical FOV from the square lattice geometry would be two multiplied by the angular acceptance range of θ2. In a theoretical test case scenario for a planar construct with Δn=0.006 and square lattice waveguide geometry θwg=0°, the FOV would be 15.2° (θ1=θ2=7.6°).

The geometry can alternatively be a radial geometry. In such a case, the LWEL can be term a Radially Distributed LWEL (RD-LWEL). Focusing the input beam onto the entrance face of the luminescent photopolymerizable material results in a radial arrangement of cylindrical waveguides form. As demonstrated by Lin et al (See more for example Lin, H et al., Advanced Optical Materials 2019, 7, 1801091; Lin, H., et al., Advanced Optical Materials 2019, 7, 1801487), the radial distribution of cylindrical waveguides with obliquely inscribed waveguides ±33° (Δn=0.001) results in a FOV of ≈115°, as the acceptance ranges for the waveguide subpopulations ranged from −57.6° to +57.6° (FIG. 6).

It has been shown herein that radial geometries give superior fields of view as compared with square geometries. Preferably, the geometry is a radial geometry. A radial geometry is preferably achieved by exposing the sol to light through a square grid mask with a cylindrical lens or Fresnel lens to converge or diverge the incident light beam through the photosensitive sol. The geometry can, however, also be a square geometry. Such a case can be achieved where the incident light beam is collimated only, so there is no Fresnel lens or cylindrical lens, so the light beams do not converge through the sample and remain straight.

Preferably, the sol is exposed to light in the selected patterned geometry. Preferably, patterning is achieved by exposing the photosensitive sol to light through a mask suitable for achieving selected geometry, e.g. having the selected geometry. Square geometries can, for example, be achieved by exposure through a mask with a square grid. Radial geometries can be achieved by exposing the sol to light through a square grid mask with a cylindrical lens or Fresnel lens to converge or diverge the incident light beam through the photosensitive sol.

The present invention also relates to a thin luminescent polymer film, preferably an LWEL, obtained or obtainable, preferably obtained, by a method as hereinbefore described.

The present invention also provides a photosensitive sol for the fabrication of a thin luminescent polymer film, preferably a luminescent waveguide-encoded lattice, the sol comprising:
one or more monomers;
at least one photoinitiator; and
at least one luminophore suitable for luminescence downshifting.

The photoinitiator may be responsible for the photosensitivity of the sol. It is preferred that the photoinitiator is suitable for decaying to yield a transparent material. In other words, the photoinitiator should preferably be, or should preferably decay to yield a product which is, transparent in the visible region. This desirably minimises losses due to parasitic absorption, maximising the performance of the device for light harvesting applications, e.g. for use with an adjacent or underlying cell, such as a PV cell. It has been found that bis(ls-cyclopentandienyl) bis(2,6-difluoro-3-(1H-pyrrol-yl)-phenyl) titanium(IV) advantageously exhibits desirable levels of visible light absorbance, enabling good levels of LWEL formation, while also decaying to yield a transparent material, minimising parasitic absorption of light.

Preferably, the photoinitiator is a transition-metal-based photoinitiator, preferably a titanium-based photo-initiator. Preferably, the photo-initiator is a metallocene-based photoinitiator, preferably a titanocene-based photoinitiator. Most preferably, the photoinitiator is bis(ls-cyclopentandienyl) bis(2,6-difluoro-3-(1H-pyrrol-yl)-phenyl) titanium(IV).

The photosensitive sol comprises one or more monomers, i.e. one or more types of monomers. The nature of the monomers need not be particularly limited, and the skilled person will be aware of certain examples which are suitable for use in the fabrication of waveguide-encoded lattices. Preferred monomers include monomers having at least one polymerisable functional group selected from epoxide, vinyl ether, lactone, acetal, cyclic ether, oxetane, acrylate, preferably methacrylate.

The one or more monomers preferably includes acrylate monomers and/or epoxide monomers. The one or more monomers preferably comprises organosiloxane monomers, preferably wherein the siloxane is a polysiloxane, preferred organo groups being acrylate-containing or epoxide-containing groups. Said another way, the one or more monomers preferably comprises monomers having —Si—O—, more preferably —O—Si—O— groups.

The sol preferably comprises epoxide monomers and acrylate monomers in a volume ratio of between 5:1 to 1:5, more preferably 3:1 to 1:3, still more preferably 3:2 to 2:3, yet more preferably about 1:1. Alternatively, or in addition, the sol preferably comprises epoxide monomers and acrylate monomers in a wt ratio of between 5:1 to 1:5, more preferably 3:1 to 1:3, still more preferably 3:2 to 2:3, yet more preferably about 1:1

Preferably, the one or more monomers comprises one or more types of acrylate monomers. Preferred acrylate monomers are methacrylate monomers. Preferred acrylate monomers comprise the following group:

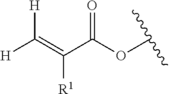

wherein R¹ is H or alkyl, preferably C1-C8 alkyl, more preferably methyl; and
the wavy line denotes a link to another chemical functionality, the identity of which is not intended to be particularly limited.

Preferred acrylate monomers are acrylate-siloxane monomers. It will be understood that such a monomer comprises at least one polymerisable acrylate group, in addition to a siloxane functionality. The one or more monomers may comprise an ingredient which is a polysiloxane with free polymerisable acrylate functional groups. A preferred example is a polysiloxane derived from polymerisation of MAPTMS, e.g. by acid catalysis, having free polymerisable acrylate groups.

Preferred acrylate monomers have the following formula:

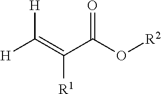

wherein R¹ is alkyl, preferably C1-C8 alkyl, more preferably methyl; and
R² is a siloxane-containing group, preferably a polysiloxane-containing group.

It is particularly preferred that the one or more monomers comprises an ingredient having a repeating unit of the following formula:

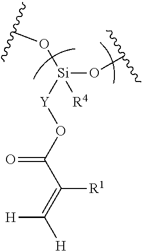

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group; and
R⁴ is H, OH, or an alkyl or an alkoxy group, preferably a C1-C8 alkyl or C1-C8 alkoxy group, more preferably a C1-C2 alkyl or C1-C2 alkoxy group.

Wavy lines denote a point of attachment to other chemical groups, e.g. end groups, a repeat of the unit, or a different unit.

It will be understood that polymerisation can proceed via polymerisation of the acrylate groups, in order to form the polymer host.

It is particularly preferred that R¹ is methyl, Y is propylene, and R⁴ is methyl or a point of attachment to another repeating group. Such a repeating unit can be derived from the polymerisation of MAPTMS using an acid catalyst, e.g. HCl.

Such an ingredient may alternatively or additionally have a unit of the following formula:

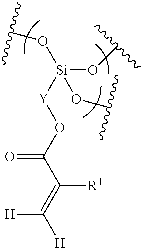

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group; and
R⁴ is H, OH, or an alkyl or an alkoxy group, preferably a C1-C8 alkyl or C1-C8 alkoxy group, more preferably a C1-C2 alkyl or C1-C2 alkoxy group;
Wavy lines denote a point of attachment to other chemical groups, e.g. end groups, a repeat of the unit, or a different unit.

Such a repeat unit is understood to be tri-functional, leading to branching.

It is particularly preferred that the one or more monomers comprises a polymer structure having the following formula:

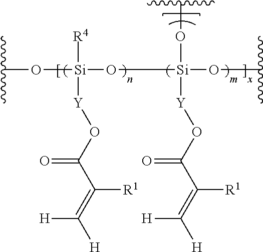

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and
R¹, R⁴, and Y may at each occurrence be the same or different, preferably the same.

Wavy lines denote a point of attachment to other chemical groups, e.g. end groups.

n and m are independently selected as a fraction from 0 to 1, where n+m=1.

The ratio of the values of n:m may be between 100:0 to 0:100. Preferably, the ratio of the values of n:m is 50:50 to 99:1, preferably 60:40 to 90:10, more preferably 65:35 to 85:15. Preferably, the ratio of the values of m:n is 50:50 to 99:1, preferably 60:40 to 90:10, more preferably 65:35 to 85:15. Preferably, the ratio of the values of n:m is 80:20 to 20:80, preferably 70:30 to 30:70, more preferably 60:40 to 40:60.

It is particularly preferred that the one or more monomers comprises an ingredient having the following formula:

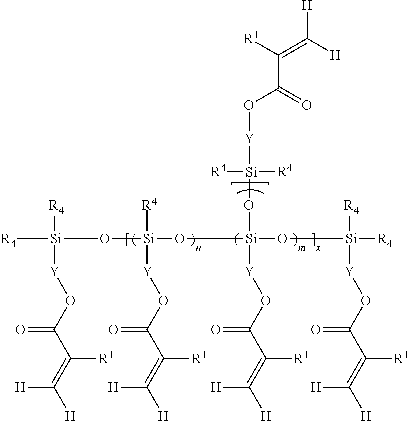

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group; and
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25.
R1, R⁴, Y, may at each occurrence be the same or different, preferably the same.

As described above, n and m are independently selected as a fraction from 0 to 1, where n+m=1.

Preferably, the photosensitive sol comprises one or more types of epoxide monomers. Preferably, epoxide monomers have a plurality, e.g. 2, epoxide groups. Preferred epoxide monomers are epoxide-siloxane monomers. It will be understood that such a monomer comprises at least one polymerisable epoxide group, in addition to a siloxane group, preferably a polysiloxane group. A preferred example of this is p-PDMS.

Preferred epoxide monomers have the following formula:

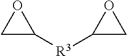

wherein R³ is a linking group, which may be substituted or unsubstituted, branched or unbranched, and which may optionally contain one or more heteroatoms.

R³ preferably comprises a group of the following formula:

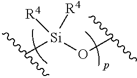

more preferably a group of the following formula:

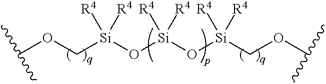

wherein
R⁴ denotes H, OH, or an alkyl or an alkoxy group, preferably a C1-C8 alkyl or C1-C8 alkoxy group, more preferably a C1-C2 alkyl or C1-C2 alkoxy group;
p is an integer from 0-50, preferably 0-20, more preferably 1-10, still more preferably 20; and
q is an integer from 0 to 12, preferably 2 to 8, still more preferably 3 to 5.
wavy lines denote a point of attachment to other chemical groups, or—if R³ consists of the above formulae—a point of attachment to the depicted epoxide groups.

Preferably, R³ consists of:

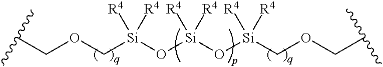

wherein
R⁴ denotes H, OH, or an alkyl or an alkoxy group, preferably a C1-C8 alkyl or C1-C8 alkoxy group, more preferably a C1-C2 alkyl or C1-C2 alkoxy group;
p is an integer from 0-50, preferably 0-20, more preferably 1-10, still more preferably 20; and
q is an integer from 1 to 12, preferably 2 to 8, still more preferably 3 to 5.

Particularly preferred epoxide monomers include p-PDMS and EEC.

Preferably, the one or more monomers comprises at least one type of epoxide monomer, preferably an epoxide-siloxane monomer, more preferably an epoxide-polysiloxane monomer, and at least one type of acrylate monomer, preferably an acrylate-siloxane monomer, more preferably an acrylate-siloxane monomer. Preferably, the wt ratio of epoxide monomers to acrylate monomers is between 5:1 to 1:5, more preferably 3:1 to 1:3, still more preferably 3:2 to 2:3, yet more preferably about 1:1.

It is preferred that the one or more monomers comprise organosiloxane monomers, preferably wherein the siloxane is a polysiloxane. This component is thought to improve the mechanical properties of the polymer. It will be understood that the organo group preferably contributes the polymerisable groups. Preferred organo groups are acrylate-containing, preferably methacrylate-containing, and epoxide-containing groups.

Preferably, the sol comprises:
an acrylate monomer, preferably an acrylate-siloxane monomer, more preferably wherein the siloxane is a polysiloxane;
a first epoxide monomer, preferably an epoxide-siloxane monomer, more preferably wherein the siloxane is a polysiloxane
a second epoxide monomer.

It has been found that the combination of an epoxide monomer and an acrylate monomer leads to improved mechanical properties, such as reduced brittleness, e.g. as compared with the use of an acrylate monomer alone. It is thought that the use of an acrylate monomer, which is preferably an acrylate-siloxane monomer, more preferably wherein the siloxane is a polysiloxane, results in good Δn, as defined herein. It is also thought that the presence of Si—O bonds, afforded by the presence of an organosiloxane component, offers refractive index close to glass to minimise losses to reflection. Such bonds are also advantageously transparent in the visible region.

For example, it is particularly preferred that the one or more monomers comprises:
a polysiloxane derived from polymerisation of MAPTMS, having free polymerisable acrylate groups
   p-PDMS; and
   EEC.

It is also particularly preferred that the one or more monomers comprises:
p-PDMS;
EEC; and
an ingredient comprising a polymer structure having the following formula:

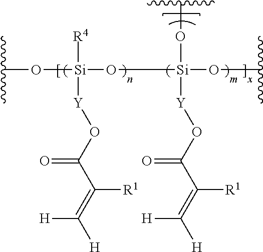

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and
R¹, R⁴, and Y may at each occurrence be the same or different, preferably the same.

The sol may comprise other ingredients and additives. Examples include solvents, hydrogen donors, and co-initiators.

The sol comprises at least one luminophore suitable for luminescence downshifting. Such a luminophore is defined herein as being suitable for absorbing incident light at certain wavelengths and emitting light at different wavelengths. Luminophores can advantageously be used to obtain spectral tuning to an adjacent cell. The exact identity of the luminophore need not be particularly limited, and certain examples will be known to the skilled person, which may be suitable for different applications. Preferred features and examples of the luminophore are discussed below.

It is preferred that the luminophore absorbs incident light (high absorption coefficient) at wavelengths where an intended adjacent cell, e.g. PV cell, has poor quantum efficiency. This means that the LWEL can advantageously harvest light at wavelengths the cell cannot. The exact wavelengths of interest will therefore differ depending on the exact nature of the cell. However, the luminophore preferably has an absorbance peak in the range of 300 to 700 nm, more preferably 325 to 600 nm, still more preferably 350 to 550 nm, yet more preferably 400 to 550 nm, still more preferably 450 to 550 nm. Such values may be optimized for a c-Si PV cell.

It is preferred that the luminophore has high transmittance, which is important to avoid parasitic absorption and to convey light to the underlying cell, e.g. PV cell. The luminophore preferably has a transmittance of greater than 90%, more preferably greater than 95%, still more preferably greater than 98%, yet more preferably greater than 99%, e.g. about 100% at wavelengths of interest. Wavelengths of interest are understood to be those at which the luminophore does not absorb, as well as those at which an underlying cell, e.g. PV cell, has good absorbance efficiency. Preferred wavelengths for the aforementioned transmittance values are greater than 500 nm, e.g. greater than 550 nm. Other preferred wavelengths are those given in the immediately preceding and immediately succeeding paragraphs.

It is preferred that the luminophore emits fluorescence at wavelengths where an intended adjacent cell, e.g. PV cell, has good quantum efficiency. This means that the LWEL can advantageously spectrally tune light to match the optimum performance range of the adjacent cell. Accordingly, the luminophore preferably has an emission peak at greater than 400 nm, preferably greater than 420 nm, still more preferably greater than 450 nm, yet more preferably greater than 475 nm, yet more preferably greater than 500 nm, e.g. greater than 550 nm. Preferably, any such peak occurs at a wavelength of less than 750 nm, preferably less than 700 nm, yet more preferably less than 650 nm. Preferred ranges are therefore between 400 to 750 nm, more preferably 450 to 700 nm, still more preferably 500 to 650 nm, e.g. 550 to 650 nm. Such values may be optimized for a c-Si PV cell.

It is also preferred that the luminophore has a high photoluminescence quantum yield (PLQY) and long-term thermal stability and photostability.

Preferably, the luminophore is selected from the group consisting of polymeric or molecular conjugated organic materials such as perylene, coumarin, naphthalimide, poly(fluorene), or benzothiadazole derivatives. More preferably, the luminophore is selected from perylene diimides, e.g. Lumogen Red or Lumogen Orange, 7-amino coumarins, e.g. Coumarin 153, napthalimides, e.g. Lumogen Violet, and poly(fluorene)s, e.g Lumogen Yellow. Still more preferably, the luminophore is selected from:
2-(2-ethylhexyl)-6,7-dimethoxy-1H-benzo[de]isoquinoline-1,3(2H)-dione (commercial name: Lumogen Violet)
N,N′-bis(2,6-di-tert-butylphenyl)perylene-3,4,9,10-bis(dicarboximide) (commercial name: Lumogen Orange)
9-(Trifluoromethyl)-2,3,6,7-tetrahydro-1H,5H,11H-pyrano[2,3-f]pyrido[3,2,1-ij]quinolin-11-one (commercial name: Coumarin 153)
N,N′-bis(2,6-diisopropylphenyl)-1,6,7,12-tetraphenoxyperylene-3,4:9,10-tetracarboxdiimide (commercial name: Lumogen Red)
3,9-bis(2-methylpropyl) 4,10-dicyanoperylene-3,9-dicarboxylate (commercial name: Lumogen Yellow)
Poly(9,9-dioctylfluorene-alt-benzothiadiazole) (commercial name: F8BT)

It is particularly preferred that the Lumogen is 2-(2-ethylhexyl)-6,7-dimethoxy-1H-benzo[de]isoquinoline-1,3(2H)-dione (commercial name: Lumogen Violet) or N,N′-bis(2,6-di-tert-butylphenyl)perylene-3,4,9,10-bis(dicarboximide) (commercial name: Lumogen Orange) or 3,9-bis(2-methylpropyl) 4,10-dicyanoperylene-3,9-dicarboxylate (commercial name: Lumogen Yellow), more preferably 3,9-bis(2-methylpropyl) 4,10-dicyanoperylene-3,9-dicarboxylate (commercial name: Lumogen Yellow). Lumogen Yellow is well placed for indoor spectral tuning as the absorption of Lumogen Yellow overlaps well with the first peak in the white LED spectrum, and the emission of Lumogen Yellow overlaps well with a higher external quantum efficiency range of silicon PV.

It is preferred that the luminophore is comprised within the polymer host. In other words, preferably the polymer host comprises the luminophore. By combining the use of a luminophore suitable for luminescence downshifting within a waveguide-encoded lattice, the LWEL produced by the method of the present invention advantageously both expands the field of view (FoV) and spectrally tunes light for the desired application.

The sol may comprise one or more dyes with a determinable, e.g. large, Stokes shift, which may enable the performance of the film to be maximized by the minimisation of reabsorption losses. Preferred Stokes shifts are greater than 15 nm, more preferably greater than 20 nm, still more preferably greater than 30 nm, e.g. greater than or equal to about 35 nm. Lumogen Red and Lumogen Violet are preferred examples.

The present invention also provides a method of preparing a photosensitive sol as hereinbefore described, the method comprising mixing together:
the one or more monomers;
the at least one photoinitiator; and
the at least one luminophore suitable for luminescence downshifting.

The fabrication process preferably comprises a preliminary step of preparing the photosensitive sol. Such a step preferably comprises mixing together:
the one or more monomers;
the at least one photoinitiator; and
the at least one luminophore suitable for luminescence downshifting.

The fabrication process may comprise preliminary steps of:
preparing a first sol;
preparing a second sol; and
combining the first and second sols to give the photosensitive sol.

It is preferred that at least one of the first and second sol comprises at least one photoinitiator. It is also preferred that at least one of the first and second sol comprises the least one luminophore suitable for luminescence downshifting. Alternatively, a photoinitiator and luminophore can be added separately.

Preparing at least one of the first or second sol preferably comprises preparing a polysiloxane. This may be achieved by mixing a polymerisation catalyst, preferably an acid, more preferably hydrochloric acid, with one or more monomers comprising a group suitable for the formation of a polysiloxane, a preferred example of which is MAPTMS. Preferably, such a preparation retains chemical groups suitable for polymerisation in the fabrication of the film, preferably acrylate groups. Such a preparation enables control over the sol viscosity and allows tuning of the kinetics of the photopolymerisation process. It is preferred that the polysiloxane comprises a polymer structure having the following formula:

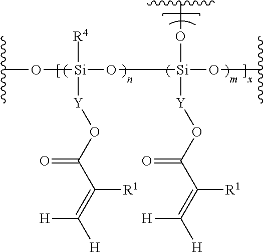

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and
R¹, R⁴, and Y may at each occurrence be the same or different, preferably the same.

It is particularly preferred that the second sol comprises one or more epoxide monomers, preferably epoxide-siloxane monomers, more preferably epoxide-polysiloxane monomers. It is also particularly preferred that preparing the first sol comprises preparing a polysiloxane, preferably by mixing a polymerisation catalyst, preferably an acid, more preferably hydrochloric acid, with a monomer comprising a group suitable for the formation of a polysiloxane, preferably MAPTMS.

Preferably at least one of the first and second sol comprises acrylate monomers, preferably acrylate-siloxane monomers, more preferably acrylate-polysiloxane monomers. Preferably at least one of the first and second sol one or more, preferably two, epoxide monomers, preferably epoxide-siloxane monomers, more preferably epoxide-polysiloxane monomers.

The present invention also provides a method of fabricating a thin luminescent polymer film, the method comprising:
exposing a photosensitive sol as hereinbefore described to light in a selected patterned geometry.

The fabrication process comprises exposing the photosensitive sol to light. This preferably initiates polymerisation of the sol. Preferably, the sol is exposed to light in a selected patterned geometry. Preferred geometries, and means for achieving this patterning, are discussed in more detail below.

The fabrication process thus preferably comprises a fabrication process comprising the polymerisation of a photosensitive sol. The propagation of such a polymerisation may be characterised by the self-trapping of light by the polymer host, i.e. by the nascent polymer host, which is derived from polymerisation of the sol.

Said another way, the polymerisation can be characterised by formation of a polymer host, and the polymerisation can be propagated by self-trapping of light by the polymer host, i.e. by the nascent polymer host. The polymer host provides the medium in which the waveguide lattice in encoded.

The polymerisation of the sol is preferably initiated by the photoinitiator. It will be understood that a photoinitiator is a species suitable for initiating polymerisation by absorbing light in the spectrum of incident light. Incident light can be incident natural light, e.g. sunlight, and/or incident artificial light, e.g. LED light, preferably white LED light. The exact type of photoinitiator need not be particularly limited, and certain examples will be known to those skilled in the art. It is preferred that the photoinitiator is suitable for initiating polymerisation by absorbing light in the visible range.

In some methods, the type of polymerisation need not be particularly limited. However, it is preferred that the polymerisation is a cationic polymerisation, a free radical polymerisation, or a combination of the two. The type of photoinitiator may be chosen accordingly. A co-initiator may also be used. In the case of cationic polymerisations, preferred monomers are monomers comprising at least one polymerisable functional group selected from epoxide, vinyl ether, lactone, acetal, cyclic ether, and oxetane. In the case of free radical polymerisations, preferred monomers are acrylate, preferably methacrylate, monomers. As one non-limiting example, the polymerisation may comprise the free radical polymerisation of an acrylate monomer, and the cationic polymerisation of an epoxide monomer.

The polymerisation of the method of the present invention yields a polymer host, fabricated from the photosensitive sol. A purpose of the polymer host is to provide the medium of which the LWEL is formed. As discussed previously, the self-trapping of light by the polymer host contributes to the formation of the waveguide-enclosed lattice. Preferred features and examples of the polymer host are discussed below. The nature of the polymer host need not be particularly limited, and the skilled person will be aware of certain examples which are suitable for use in the formation of waveguide-encoded lattices. It will be understood that the nature of the polymer host and the photosensitive sol are closely linked, the former being derived from polymerisation of components of the latter.

For the more effective angular collection of light by each waveguide channel, a high refractive index contrast is preferred between the channel and the surrounding matrix. The polymer host therefore preferably provides a refractive index contrast (Δn) of greater than 0.001, more preferably greater than 0.0025, still more preferably greater than 0.005.

As an example, acrylate chemistries possess high refractive index contrast, with Δn>0.001. Preferably, the polymer host comprises an acrylate component. Such a component may be derived from the polymerisation of an acrylate monomer in a sol as hereinbefore described.

Preferably, the film has a field of view of greater than 10 degrees, more preferably greater than 15 degrees, still more preferably greater than 18 degree, yet more preferably greater than 25 degrees, greater than 35 degrees, or greater than 40 degrees. The field of view can be determined according to the protocol explained in the Examples.

To better facilitate self-trapping of light, it is preferred that the polymer host is optically transparent.

It is also preferred that photopolymerisation chemistry is insensitive to phase and amplitude fluctuations at femtosecond (fs) timescales, which are typically seen in incoherent sources such as LEDs. By way of example, the slow evolution of organosiloxane and epoxide polymerisation (ms to minutes) renders the system insensitive to fs fluctuations. They only respond to the time-averaged optical field, which advantageously allows a LED beam to self-trap. Preferably, the polymer host comprises an organosiloxane component, preferably a polyorganosiloxane component. Preferred organo groups are epoxide-containing or acrylate-containing groups.

Preferably, the polymer host comprises an epoxide component, preferably an epoxide-siloxane component, more preferably an epoxide-polysiloxane, and/or an acrylate component, preferably an acrylate-siloxane component, more preferably an acrylate-polysiloxane component.

It has been found that composite sols comprising both acrylate and epoxide monomers maintained good formation of cylindrical waveguide channels, along with improved the thermomechanical robustness of the polymer films: the use of acrylate monomers alone was found to lead to high brittleness. Preferably, the polymer host comprises an acrylate component and an epoxide component. In other words, the polymer host is preferably an acrylate-epoxide composite. Preferably, the volume ratio of the epoxide component to the acrylate component is between 5:1 to 1:5, more preferably 3:1 to 1:3, still more preferably 3:2 to 2:3, yet more preferably about 1:1. Preferably, the wt ratio of the epoxide component to the acrylate component is between 5:1 to 1:5, more preferably 3:1 to 1:3, still more preferably 3:2 to 2:3, yet more preferably about 1:1. Such components may be derived from the polymerisation of acrylate monomers and epoxide monomers in a sol as hereinbefore described.

The selected geometry is preferably a square geometry or a radial geometry. It has been shown herein that radial geometries give superior fields of view as compared with square geometries. Preferably, the geometry is a radial geometry. A radial geometry is preferably achieved by exposing the sol to light through a square grid mask with a cylindrical lens or Fresnel lens to converge or diverge the incident light beam through the photosensitive sol. The geometry can, however, also be a square geometry. Such a case can be achieved where the incident light beam is collimated only, so there is no Fresnel lens or cylindrical lens, so the light beams do not converge through the sample and remain straight.

Preferably, patterning is achieved by exposing the photosensitive sol to light through a mask suitable for achieving selected geometry, e.g. having the selected geometry. Square geometries can, for example, be achieved by exposure through a mask with a square grid. Radial geometries can be achieved by exposing the sol to light through a square grid mask with a cylindrical lens or Fresnel lens to converge or diverge the incident light beam through the photosensitive sol.

Preferably, the method comprises a step of irradiating with light. Preferably, this step occurs after polymerisation. The light is preferably white light, e.g. white LED light. This is preferably done to degrade the photoinitiator. This is preferably done in conjunction with a long pass filter, which is preferably configured to prevent passage of light having a wavelength having light of less than 520 nm, more preferably less 500 nm, still more preferably less than 495 nm, in order to prevent luminophore photodegradation. The irradiation is preferably of the whole polymer host or film. It has been found that such a step leads to fluorescence enhancement.

The present invention also provides a thin luminescent polymer film, preferably an LWEL, obtained or obtainable, preferably obtained, by a method as hereinbefore described.

The present invention also provides a thin luminescent polymer film, preferably an LWEL, comprising:
a patterned waveguide geometry; and
at least one luminophore suitable for luminescence downshifting.

Such a film can be obtained by methods as hereinbefore described.

The geometry is preferably a square geometry or a radial geometry, more preferably a radial geometry.

The thin luminescent polymer film, preferably an LWEL, comprises at least one luminophore suitable for luminescence downshifting. Such a luminophore is defined herein as being suitable for absorbing incident light at certain wavelengths and emitting light at different wavelengths. Luminophores can advantageously be used to obtain spectral tuning to an adjacent cell. The exact identity of the luminophore need not be particularly limited, and certain examples will be known to the skilled person, which may be suitable for different applications. Preferred features and examples of the luminophore are discussed below.

It is preferred that the luminophore absorbs incident light (high absorption coefficient) at wavelengths where an intended adjacent cell, e.g. PV cell, has poor quantum efficiency. This means that the LWEL can advantageously harvest light at wavelengths the cell cannot. The exact wavelengths of interest will therefore differ depending on the exact nature of the cell. However, the luminophore preferably has an absorbance peak in the range of 300 to 700 nm, more preferably 325 to 600 nm, still more preferably 350 to 550 nm, yet more preferably 400 to 550 nm, still more preferably 450 to 550 nm. Such values may be optimized for a c-Si PV cell.

It is preferred that the luminophore has high transmittance, which is important to avoid parasitic absorption and to convey light to the underlying cell, e.g. PV cell. The luminophore preferably has a transmittance of greater than 90%, more preferably greater than 95%, still more preferably greater than 98%, yet more preferably greater than 99%, e.g. about 100% at wavelengths of interest. Wavelengths of interest are understood to be those at which the luminophore does not absorb, as well as those at which an underlying cell, e.g. PV cell, has good absorbance efficiency. Preferred wavelengths for the aforementioned transmittance values are greater than 500 nm, e.g. greater than 550 nm. Other preferred wavelengths are those given in the immediately preceding and immediately succeeding paragraphs.

It is preferred that the luminophore emits fluorescence at wavelengths where an intended adjacent cell, e.g. PV cell, has good quantum efficiency. This means that the LWEL can advantageously spectrally tune light to match the optimum performance range of the adjacent cell. Accordingly, the luminophore preferably has an emission peak at greater than 400 nm, preferably greater than 420 nm, still more preferably greater than 450 nm, yet more preferably greater than 475 nm, yet more preferably greater than 500 nm, e.g. greater than 550 nm. Preferably, any such peak occurs at a wavelength of less than 750 nm, preferably less than 700 nm, yet more preferably less than 650 nm. Preferred ranges are therefore between 400 to 750 nm, more preferably 450 to 700 nm, still more preferably 500 to 650 nm, e.g. 550 to 650 nm. Such values may be optimized for a c-Si PV cell.

It is also preferred that the luminophore has a high photoluminescence quantum yield (PLQY) and long-term thermal stability and photostability.

Preferably, the luminophore is selected from the group consisting of polymeric or molecular conjugated organic materials such as perylene, coumarin, naphthalimide, poly(fluorene), or benzothiadazole derivatives. More preferably, the luminophore is selcted from perylene diimides, e.g. Lumogen Red or Lumogen Orange, 7-amino coumarins, e.g. Coumarin 153, napthalimides, e.g. Lumogen Violet, and poly(fluorene)s, e.g. Lumogen Yellow. Still more preferably, the luminophore is selected from:
2-(2-ethylhexyl)-6,7-dimethoxy-1H-benzo[de]isoquinoline-1,3(2H)-dione (commercial name: Lumogen Violet)
N,N′-bis(2,6-di-tert-butylphenyl)perylene-3,4,9,10-bis(dicarboximide) (commercial name: Lumogen Orange)
9-(Trifluoromethyl)-2,3,6,7-tetrahydro-1H,5H,11H-pyrano[2,3-f]pyrido[3,2,1-ij]quinolin-11-one (commercial name: Coumarin 153)
N,N′-bis(2,6-diisopropylphenyl)-1,6,7,12-tetraphenoxyperylene-3,4:9,10-tetracarboxdiimide (commercial name: Lumogen Red)
3,9-bis(2-methylpropyl) 4,10-dicyanoperylene-3,9-dicarboxylate (commercial name: Lumogen Yellow)
Poly(9,9-dioctylfluorene-alt-benzothiadiazole) (commercial name: F8BT)

It is particularly preferred that the Lumogen is 2-(2-ethylhexyl)-6,7-dimethoxy-1H-benzo[de]isoquinoline-1,3(2H)-dione (commercial name: Lumogen Violet) or N,N′-bis(2,6-di-tert-butylphenyl)perylene-3,4,9,10-bis(dicarboximide) (commercial name: Lumogen Orange) or 3,9-bis(2-methylpropyl) 4,10-dicyanoperylene-3,9-dicarboxylate (commercial name: Lumogen Yellow), more preferably 3,9-bis(2-methylpropyl) 4,10-dicyanoperylene-3,9-dicarboxylate (commercial name: Lumogen Yellow). Lumogen Yellow is well placed for indoor spectral tuning as the absorption of Lumogen Yellow overlaps well with the first peak in the white LED spectrum, and the emission of Lumogen Yellow overlaps well with a higher external quantum efficiency range of silicon PV.

It is preferred that the luminophore is comprised within the polymer host. In other words, preferably the polymer host comprises the luminophore. By combining the use of a luminophore suitable for luminescence downshifting within a waveguide-encoded lattice, the LWEL produced by the method of the present invention advantageously both expands the field of view (FoV) and spectrally tunes light for the desired application.

The sol may comprise one or more dyes with a determinable, e.g. large, Stokes shift, which may enable the performance of the film to be maximized by the minimisation of reabsorption losses. Preferred Stokes shifts are greater than 15 nm, more preferably greater than 20 nm, still more preferably greater than 30 nm, e.g. greater than or equal to about 35 nm. Lumogen Red and Lumogen Violet are preferred examples.

The present invention also provides an apparatus comprising:
a photovoltaic (PV) cell; and
a film, preferably an LWEL, as described herein assembled thereon.

As has been described, a film, preferably LWEL, as provided by the present invention offers improved performance to an adjacent or underlying PV cell. This includes the provision of an improved field of view, and spectral tuning to the underlying cell, especially advantageous in diffuse and/or indoor light conditions.

The PV cell is preferably an indoor PV cell, in other words a PV cell intended for indoor applications. Example PV cells include dye-sensitised solar cells, organic PV cells, and perovskite PV cells. The identity of the luminophore can be chosen so as to optimise a match to the spectral requirements of the PV cell in question.

The present invention also provides the use or application of any other aspect of the present invention to enhance photovoltaic cell performance. It is preferred that the use or application is to enhance photovoltaic cell performance under indoor lighting or under diffuse light conditions. Preferably, the use or application is to enhance photovoltaic cell performance under indoor lighting for powering devices in the Internet-of-Things, enhance photovoltaic cell performance under outdoor lighting, particularly in cloudy weather (diffuse light) for residential solar panels, enhance photovoltaic cell performance under outdoor lighting, where sunlight is generally incident on the photovoltaic cell off-angle (i.e. at wide angles with respect to the photovoltaic cell surface normal), and to residential solar panels.

### Preferred Methods

Some preferred methods of the present invention are given below.

A method of fabricating a thin luminescent polymer film, preferably a luminescent waveguide-encoded lattice (LWEL), having a patterned waveguide geometry, the method comprising:
the polymerisation of a photosensitive sol, the polymerisation preferably being characterised by the self-trapping of light,
wherein
the sol comprises at least one luminophore suitable for luminescence downshifting;
the sol comprises epoxide monomers and acrylate monomers, preferably in a wt ratio of between 5:1 to 1:5, more preferably 3:1 to 1:3, still more preferably 3:2 to 2:3, yet more preferably about 1:1.

A method of fabricating a thin luminescent polymer film, preferably a luminescent waveguide-encoded lattice (LWEL), having a patterned waveguide geometry, the method comprising:
the polymerisation of a photosensitive sol, the polymerisation preferably being characterised by the self-trapping of light,
wherein
the sol comprises at least one luminophore suitable for luminescence downshifting;
   the sol comprises at least one type of epoxide monomer, preferably an epoxide-siloxane monomer, more preferably an epoxide-polysiloxane monomer, and at least one type of acrylate monomer, preferably an acrylate-siloxane monomer, more preferably an acrylate-siloxane monomer; and
   the sol comprises epoxide monomers and acrylate monomers, preferably in a wt ratio of between 5:1 to 1:5, more preferably 3:1 to 1:3, still more preferably 3:2 to 2:3, yet more preferably about 1:1.

A method of fabricating a thin luminescent polymer film, preferably a luminescent waveguide-encoded lattice (LWEL), having a patterned waveguide geometry, the method comprising:
the polymerisation of a photosensitive sol, the polymerisation preferably being characterised by the self-trapping of light,
wherein
the sol comprises at least one luminophore suitable for luminescence downshifting; and
the sol comprises:
p-PDMS;
EEC; and
an ingredient comprising a polymer structure having the following formula:

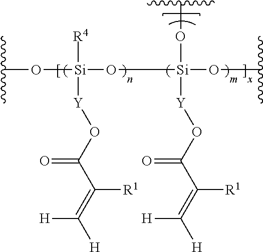

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and
R¹, R⁴, and Y may at each occurrence be the same or different, preferably the same.

A method of fabricating a thin luminescent polymer film, preferably a luminescent waveguide-encoded lattice (LWEL), having a patterned radial waveguide geometry, the method comprising:
the polymerisation of a photosensitive sol, characterised by the self-trapping of light,
wherein the sol comprises at least one luminophore suitable for luminescence downshifting.
wherein
the fabrication process comprises exposing the photosensitive sol to light and the patterning is achieved by exposing the photosensitive sol to light in the radial geometry, preferably by using a mask.

A method of fabricating a thin luminescent polymer film, preferably a luminescent waveguide-encoded lattice (LWEL), having a patterned radial waveguide geometry, the method comprising:
the polymerisation of a photosensitive sol, the polymerisation preferably being characterised by the self-trapping of light,
wherein the sol comprises at least one luminophore suitable for luminescence downshifting.
wherein the method comprises the use of at least one luminophore suitable for luminescence downshifting,
wherein
the polymerisation is initiated by light, the photosensitive sol comprises a bis(η⁵-cyclopentandienyl) bis(2,6-difluoro-3-(1H-pyrrol-yl)-phenyl) titanium(IV) photoinitiator, and the fabrication process comprises exposing the photosensitive sol to light; and
the patterning is achieved by exposing the photosensitive sol to light in the radial geometry, preferably by using a mask.

A method of fabricating a thin luminescent polymer film, preferably a luminescent waveguide-encoded lattice (LWEL), having a patterned radial waveguide geometry, the method comprising:
the polymerisation of a photosensitive sol, the polymerisation preferably being characterised by the self-trapping of light,
wherein the sol comprises at least one luminophore suitable for luminescence downshifting.
wherein the method comprises the use of at least one luminophore suitable for luminescence downshifting, preferably Lumogen Orange and/or Lumogen Violet;
wherein
the polymerisation is initiated by light, the photosensitive sol comprises a bis(ls-cyclopentandienyl) bis(2,6-difluoro-3-(1H-pyrrol-yl)-phenyl) titanium(IV) photoinitiator, and the fabrication process comprises exposing the photosensitive sol to light;
the patterning is achieved by exposing the photosensitive sol to light in the radial geometry, preferably by using a mask;
the sol comprises epoxide monomers and acrylate monomers, preferably in a wt ratio of between 5:1 to 1:5, more preferably 3:1 to 1:3, still more preferably 3:2 to 2:3, yet more preferably about 1:1; and
preferably, the sol comprises:
p-PDMS;
EEC; and
an ingredient comprising a polymer structure having the following formula:

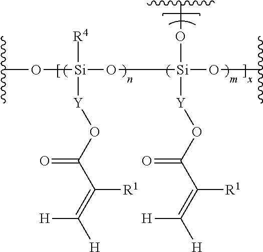

wherein
R¹ is H or alkyl, preferably C1-C8 alkyl, more preferably methyl;
Y is a linking group, preferably an alkylene group, more preferably a C1-C8 alkylene group, still more preferably a C3-C6 alkylene group;
R⁴ is H, OH, or an alkyl or an alkoxy group, preferably a C1-C8 alkyl or C1-C8 alkoxy group, more preferably a C1-C2 alkyl or C1-C2 alkoxy group;
x is an integer from 2 to 70, preferably 2 to 50, more preferably 3 to 25;
n and m are independently selected as a fraction from 0 to 1, where n+m=1; and R¹, R⁴, and Y may at each occurrence be the same or different, preferably the same.

### Examples—Section 1

### Preliminary Investigation of Luminophores

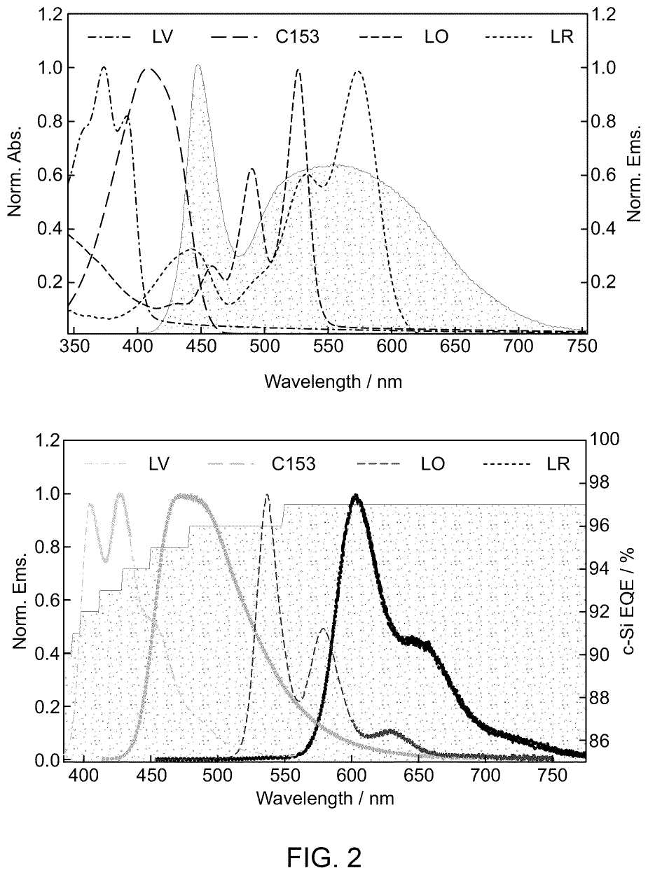

For applications harnessing indoor lighting, Luminophore candidates were selected for investigation by comparing the spectral overlap in the absorption spectrum of the luminophore with the typical emission from white LEDs, and by comparing the overlap in the fluorescence spectrum of the luminophore with the quantum efficiency of c-Si (FIG. 2).

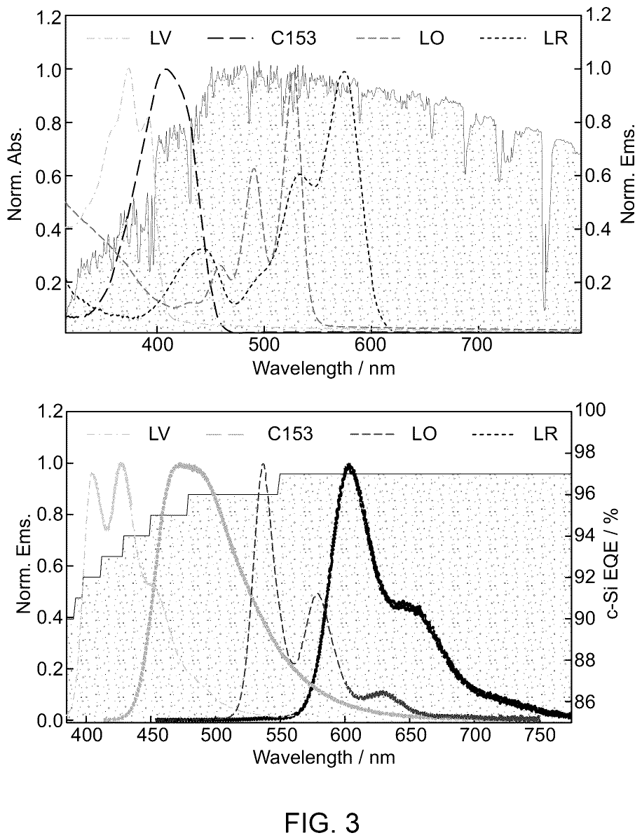

For applications harnessing outdoor lighting, Luminophore candidates were selected for investigation by comparing the spectral overlap in the absorption spectrum of the luminophore with the AM1.5G solar standard illumination, and by comparing the overlap in the fluorescence spectrum of the luminophore with the quantum efficiency of c-Si (FIG. 3).

### Preparation of Methacrylate Sol

Methacrylate sol was prepared through acid-catalyzed hydrolysis and condensation of 3-(trimethoxysilyl)propyl methacrylate (MAPTMS). This was accomplished by adding 0.30 g of 0.05 M hydrochloric acid (prepared from ACS reagent 37%, Sigma Aldrich) to 4.89 g of MAPTMS (Sigma Aldrich). This resulted in a two-phase mixture which was left to stir, for about 15 to 20 minutes, to become a homogenous, transparent colorless liquid. The mixture was then sensitized to light by adding 0.5 wt % of a titanocene-based free-radical photoinitiator [(bis(η⁵-cyclopentandienyl) bis(2,6-difluoro-3-(1H-pyrrol-yl)-phenyl) titanium(IV)](Omnirad 784, IGM Resins). Various luminophores were investigated and added at a 0.01 wt % loading. The mixture was then protected from ambient light with aluminum foil wrapping and left to stir for 6 days.

### Preparation of Epoxide Sol

Epoxide sol was prepared generally following a method as proposed by J. V. Crivello (See more for example Crivello, J. V. et al., J. Polym. Sci. A Polym. Chem., 47: 866-875) with some modifications. In brief, 3,4-epoxycyclohexylmethyl 3,4-epoxycyclohexanecarboxylate (‘EEC’, Sigma Aldrich), epoxypropoxy propyl terminate polydimethylsiloxane (8-11 cSt) (‘pPDMS’, Gelest Inc.), poly(tetrahydrofuran) (‘pTHF’, Mₙ=250, Sigma Aldrich), bis(η²-cyclopentandienyl) bis(2,6-difluoro-3-(1H-pyrrol-yl)-phenyl) titanium(IV) (‘Omnirad 784’, IGM Resins) and photoinitiator (4-octyloxyphenyl) phenyliodonium hexafluoroantimonate (‘OPPI’, Hampford Research Inc.) were added in 51%, 26%, 20%, 1.0%, and 2.0% by weight (sol mixture=2.5 g, 1.3 g, 1.0 g, 0.050 g and 0.10 g, respectively, for a 4.95 g batch). Various luminophores were investigated and added at a 0.01 wt % loading. The mixture was then protected from ambient light with aluminium foil wrapping and left to stir for at least 48 hours before use.

### Photopolymerisation

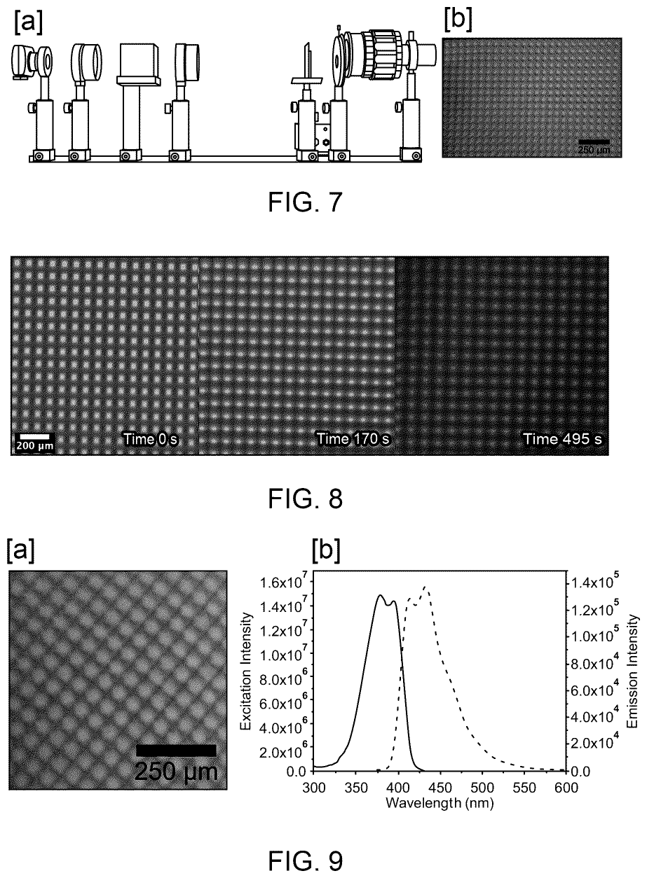

Mixtures of the organosiloxane and epoxide (0: E) sols were created in volume ratio compositions. Both components were synthesised as outlined above and left to stir for a minimum of 30 minutes to ensure homogenous mixing. Sols were then injected into customized ring cells consisting of 3D-printed thermoplastic polyurethane (TPU) spacer sandwiched between two glass slides. The TPU spacer was 3D-printed to a thickness of 1 mm. Polytetrafluoroethylene (PTFE) tape was used to form a liquid-tight seal with the glass slides when affixed together with bulldog clips. The filled ring cell was placed in front of a photomask and exposed to a collimated white LED beam (FIG. 7). In-situ monitoring of the polymerisation process can be performed by directing the transmitted light to a CCD camera and spectrometer using a beam splitter cube. Power and irradiance time are adjusted to (i) favor the self-trapping of light over the modulation instability regime (ii) maximize the refractive index contrast between the channels and surrounding matrix and (iii) prevent bleaching of the luminophore.

Using imaging optics and a CCD camera, the photochemical reactions responsible for the self-trapping and inscription of waveguides can be monitored. FIG. 8 shows the temporal evolution of the beam intensity and spatial intensity profiles of the exit face of an acrylate sqWEL with Lumogen Red (path length=2 mm) during self-trapping. Through the implementation of the amplitude mask the initially broad beam of light is divided into a square grid of individual spots, each capable of initiating free radical polymerisation of the acrylate moieties. The changes in density induce corresponding changes in refractive index along the axis of light propagation, generating cylindrical waveguides. As the self-trapping continues to its end, the beam changes from looking like the original square grid pattern and adopts a more Gaussian profile shape (time=495s).

### Investigation of Square LWELs (SqLWELs)

Acrylate Epoxy LWEL (Lumogen Violet): The luminescence downshifting properties of a LWEL consisting of a 6:4 acrylate-epoxy composite and doped with 0.007% wt Lumogen Violet luminophore were investigated, as shown in FIG. 9. The waveguides were arranged in a square array and the absorbance and photoluminescence characterisation confirmed the presence of a highly emissive species at very low concentrations (<0.01% wt). The excitation occurs in the UV region in a wavelength range of 325-420 nm, with three characteristic peaks at 360, 377 and 395 nm. The emission spectrum of the Lumogen Violet LWEL ranges between 375-500 nm, with three characteristic peaks at 414, 430 and 460 nm. These results demonstrate the potential of Lumogen Violet for spectral matching to a PV cell with poor UV response, via luminescence downshifting under solar irradiation.

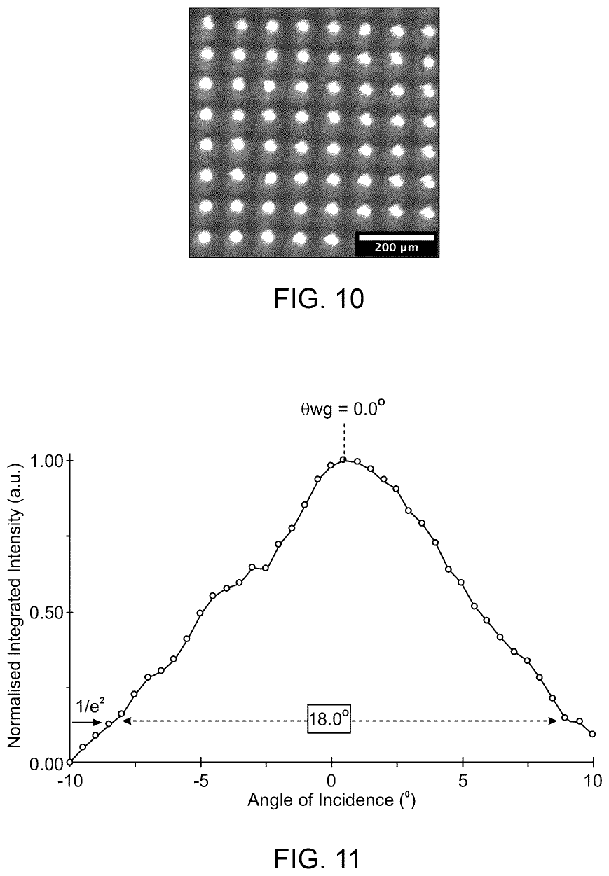

Acrylate LWEL (Lumogen Red): Transverse cross-sections (FIG. 10) of a 2 mm thick sqWEL with Lumogen Red show arrays of discrete, bright spots which correspond to the output of individual waveguides.

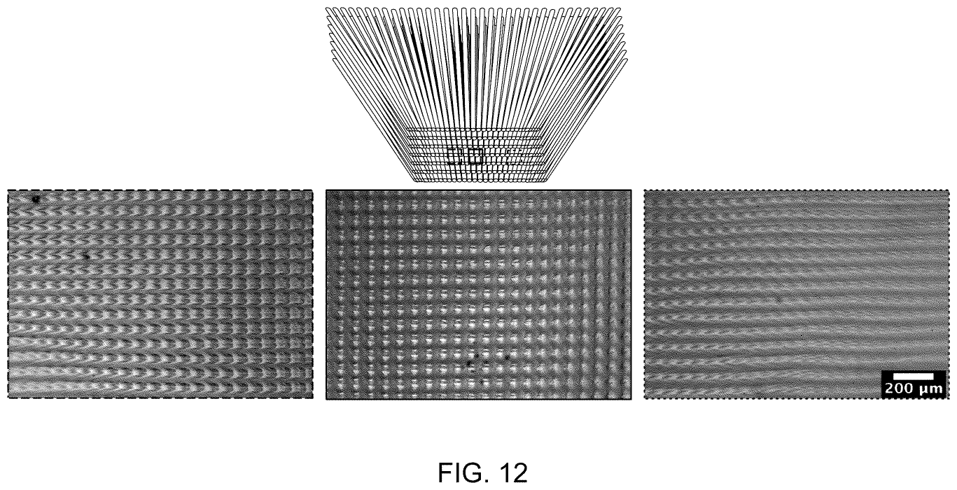

The angular acceptance range of the sqWEL was determined through previously developed methods. (See more example Lin, H et al., Advanced Optical Materials 2019, 7, 1801091; Lin, H et al., Advanced Optical Materials 2019, 7, 1801487.) In brief, light incident upon the θwg=0.0° was varied over an arc of incident angles spanning ±10° (in increments of 0.5°) probing the angular acceptance range of said waveguide population. Images were captured using a CCD camera to further quantify the light intensity output. The light collection is quantified by plots of normalized integrated intensity versus incident angle of the beam of light and was determined to be (1/e²) for the waveguide subpopulation (FIG. 11). For the sqLWEL with Lumogen Red, the angular acceptance range was reported to be [−8.9°, +9.5° ] which results in a FOV of 18.0°.

### Investigation of Radially Distributed LWELs (RD-LWELs)

Acrylate RD-LWEL (with Lumogen Red): RD-LWELs were prepared by combining a square grid amplitude mask with a cylindrical lens (i.e., Thorlabs LJ1075L2-A or Newport CKX025) and converging the incident light beam through the photosensitive sol to inscribe a radial geometry. Transverse cross-sections (FIG. 12) of the 2 mm thick RD-LWEL with Lumogen Red are shown below. The green outlined image shows arrays of discrete, bright spots which correspond to the output of individual waveguides. As the microscope probes further from the centre of the RD-LWEL, the spots begin to appear blurred. This occurs as waveguides with a larger angular tilt to them are guiding light away from the microscope camera optic axis and the light can no longer be captured (purple and blue outlined images).

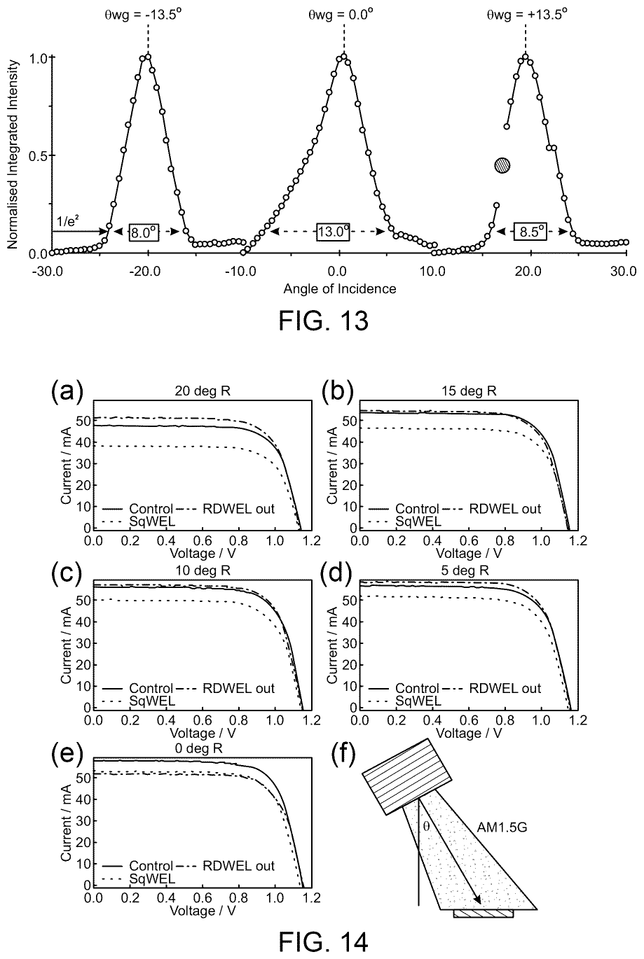

The angular acceptance range of the RD-LWEL was determined through previously developed methods (see, for example, Lin, H et al., Advanced Optical Materials 2019, 7, 1801091; Lin, H et al., Advanced Optical Materials 2019, 7, 1801487). In brief, the RD-LWEL was rotated such that light was incident upon θwg=−13.5°, 0.0° and +13.5°. At these waveguide lattice subpopulations, the light was varied over an arc of incident angles spanning ±10° (in increments of 0.5°) to probe the angular acceptance range of said waveguide subpopulations. Images were captured using a CCD camera to further quantify the light intensity output. The light collection is quantified by plots of normalised integrated intensity versus incident angle of the beam of light and was determined to be (1/e²) for each waveguide subpopulation (FIG. 13). For the RD-LWEL with Lumogen Red, the angular acceptance range was reported to be [−24.0°, +16.0°](θwg=−13.5°), [−7.5°, +5.5° ](θwg=0.0°) and [−16.0°, +24.5°](θwg=+13.5°) which results in total angular acceptance ranges of 8.0°, 13.0° and 8.5° respectively. This advantageously results in a total FOV of 45.5° (as determined by oblique θwg=±13.5°). One can imagine if the other waveguide subpopulations were probed of the RD-LWEL, this would result in a seamless panoramic FOV.

TABLE 1
Summary of FOV probing of LWEL films, with various waveguide
geometries. Light incident on film entrance face (θi), waveguide
angle probed at respective θi (θwg), waveguide acceptance
cones for respective θwg (θaccp. 1, θaccp. 2) and the
total angular acceptance range for each waveguide lattice are reported.

| | | | | | Total | |
|---|---|---|---|---|---|---|
| | | | | | angular | |
| | θi (in | | θaccp. | θaccp. | acceptance | |
| Sample ID | the air) | θwg | 1 | 2 | range | FoV |
| sqLWEL | 0.0° | 0.0° | −8.5° | +9.5° | 18° | 18° |
| (Lumogen Red) | | | | | | |
| RD-LWEL | +20.0° | +13.5° | +16.0° | +24.5 | 8.5° | 45.5° |
| (Lumogen Red) | | | | | | |
| RD-LWEL | 0.0° | 0.0° | −7.5° | +5.5° | 13.0° | |
| (Lumogen Red) | | | | | | |
| RD-LWEL | −20.0° | −13.5° | −24.0° | −16.0° | 8.0° | |
| (Lumogen Red) | | | | | | |

Angle-Dependent Solar Characterisation of RD-LWELs and sq-LWELs

FIG. 14 compares a 2 mm thick square lattice to a 1 mm thick radially-distributed lattice. This reveals an enhancement in the performance of a c-Si PV cell under angled solar light (AM1.5G). By comparing a bare PV cell (‘Control’) to the radially-distributed lattice (‘RDWEL out’), we observe an increase in the short circuit current (I_{sc}) at 20-degree incidence. Similar current-voltage curves were recorded with and without the RDWEL for angles of incidence in the range of 5 degrees to 15 degrees. Parasitic losses were observed for normal incidence. It must be noted that performance improvements here were found with a non-optimised luminophore (Coumarin 153) for spectral tuning of sunlight. Further optimisation of the luminophore, film thickness, waveguide geometry, fabrication parameters and LWEL-PV interface is expected to result in greater improvements to the I_{sc} and % PCE.

### Conclusion

The Examples have demonstrated the effective fabrication of a range of different LWELs. The LWELs benefit from expansion in the field of view (FoV), especially for radial LWELs, and an ability to spectrally tune light for the desired application. This has been shown to be beneficial for applications with underlying PV cells.

### Examples—Section 2

Herein we investigate the photopolymerization kinetics of bulk and micropatterned (i.e., WELs) monoliths formed by homopolymers and their blends, with and without a luminophore. Our objectives are to understand (i) how luminophore-photoinitiator interactions affect the photolysis rate and (ii) whether this affects the emission properties of the final material. To achieve this, we have designed a model blend based on methacrylate-siloxane and epoxy-terminated PDMS precursors in which both components can be photoinitiated by the same primary sensitizer ([(bis(η5-cyclopentadienyl) bis(2,6-difluoro-3-(1H-pyrrole-yl)-phenyl) titanium (IV)], herein referred to as Omnirad™ 784) to reduce the complexity of the system and minimize absorbance overlap. Time-resolved fluorescence quenching experiments are combined with density functional theory (DFT) calculations to understand electronic interactions between the luminophore and photoinitiator. Finally, we demonstrate how in-situ optical spectroscopy can be used to monitor micropatterning during photopolymerization and show how photobleaching of the photoinitiator affects the final photoluminescence properties.

### Design of the Luminescent Polymer System

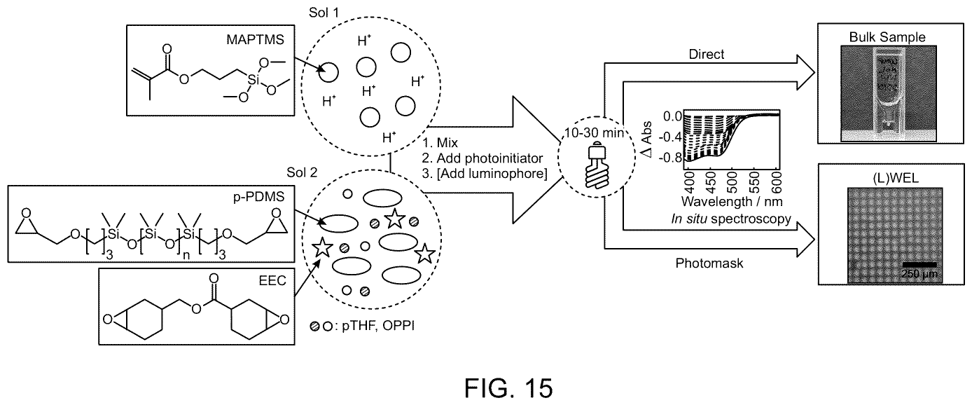

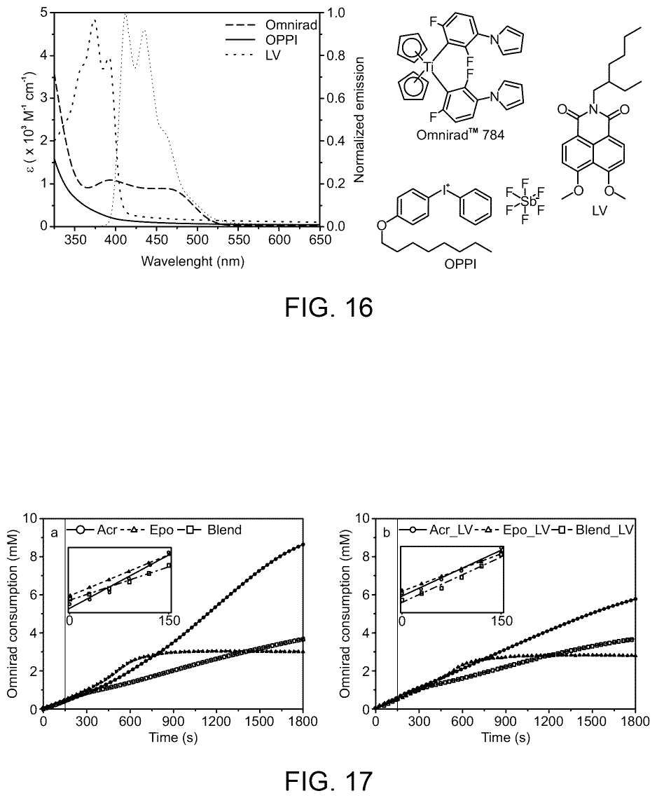

FIG. 15 presents a schematic illustration of the precursor homopolymers, the polymerization process, and representative photographs of both bulk and micropatterned (WEL) samples. In brief, the precursor polymer sols are prepared and mixed (if making a blend) before the photoinitiator and luminophore (if using) are added. The sol is then exposed to white light (halogen or LED), either directly for bulk samples or through a photomask for WEL samples. Full experimental details can be found below.

The methacrylate-substituted siloxane system (Sol 1, FIG. 15) can be used to fabricate WELs. These photopolymerizable sols were prepared through two steps. First, acid-catalyzed hydrolysis and polycondensation of trimethoxysilyl groups of precursor molecules generate the poly(siloxane) backbone. Subsequent exposure of the sol to visible light leads to photoinduced free-radical polymerization of methacrylate substituents (Scheme S1). The resultant WELs show a refractive index change (Δn) of 0.006 at the waveguide channel interface, leading to efficient light guiding through the channels. However, the organosiloxane films are extremely brittle and difficult to remove from the sample holder.

The photosensitized epoxide component system (Sol 2, FIG. 15) can also produce WELs. In this system, cationic ring-opening polymerization (ROP) occurs between the terminal epoxide groups on the precursors (3,4-epoxycyclohexylmethyl 3,4-epoxycyclohexane carboxylate (EEC), and epoxypropoxypropyl-terminated polydimethylsiloxane (p-PDMS)) upon light exposure in the presence of the photoinitiator. EEC was selected for its ability to undergo photopatterning by self-trapping and waveguide formation upon visible-light polymerization. In this system, a hydrogen donor (poly(tetrahydrofuran), pTHF) and co-initiator (4-octyloxyphenyl phenyliodonium hexafluoroantimonate, OPPI) are required to drive the reaction (Scheme S2, SI). pTHF was chosen over other hydrogen donors as it retains high polymerization rates while improving the mechanical and thermal properties of the resulting material. The refractive index change (Δn~0.001) in this system is slightly lower, but the resulting films are thermochemically robust and freestanding.

Based on the outlined properties of the individual homopolymers, we postulated that a blend of methacrylate-substituted siloxane (Acr-Sil) and epoxide (Epo) should result in films that combined the best of both systems. Screening studies demonstrated that well-defined WELs could be formed in an Acr-Sil: Epo blend ratios of both 1:1 and 3:2, resulting in free-standing films with good mechanical integrity (FIG. 1).

The choice of luminophore and photoinitiator were considered in tandem to allow us to investigate how electronic interactions between these two components influence polymerization kinetics. In previous studies on WELs, free radical polymerization of Acr-Sil was photoinitiated by Omnirad™ 784, while cationic ROP of Epo was achieved using camphorquinone (CQ) as the photoinitiator, with OPPI as a co-initiator. However, a single photoinitiator is desirable to simplify the study of reaction kinetics. Omnirad™ 784 was selected over CQ as it photolyzes during the initiation of photopolymerization, providing a convenient handle to monitor the photoinitiation kinetics. Test studies demonstrated that cationic ROP of Epo could be successfully photoinitiated using Omnirad™ 784 in conjunction with OPPI to produce WELs (see FIG. 22). We note that the Omnirad™ 784 co-initiator is required to ensure the reaction proceeds under white light rather than UV irradiation so that a single and safer light source can be used to drive the polymerization of Acr-Sil and Epo sols. We chose Lumogen® Violet (LV) as the luminophore due to its good photostability and high photoluminescence quantum yield (PLQY ~99% in toluene). Owing to the near unity PLQY, we expect no formation of triplet excited states which could result in undesired side reactions. FIG. 2 overlays the absorbance spectra of Omnirad™ 784, OPPI and LV. While Omnirad™ 784, OPPI and LV exhibit different absorbance profiles, they overlap significantly from 300-410 nm, which coincides with two key emission lines (366 nm and 405 nm) from the halogen lamp (FIG. 23). The absorbance overlap is less significant with the white LED (negligible emission from 300-400 nm), resulting in a greater proportion of the total incident photons (with wavelengths above 400 nm) being absorbed by Omnirad™ 784. As such, the fraction of photons absorbed by each component will depend strongly on the wavelength-dependence of the molar absorbance coefficient (e) and the spectral profile of the lamp, along with the relative loading of photoinitiator, photosensitizer and LV in the precursor sols (wt %).

Photolysis Kinetics within Bulk Homopolymers and Polymer Blends

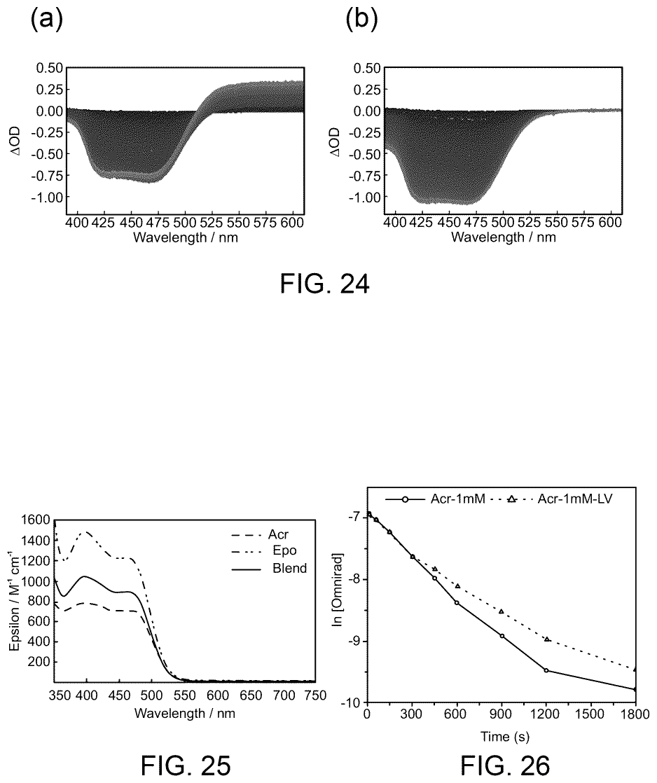

The photoinitiation process, whereby light is absorbed by Omnirad™ 784 to generate free radicals, can be studied using UV-Vis absorbance spectroscopy to extract rate constants. We used a similar approach to investigate this process in the bulk homopolymers and their blends by monitoring the molar consumption of Omnirad™ 784 under halogen lamp excitation through UV-Vis absorbance spectroscopy (FIG. 17, see FIGS. 24 to 25 for further details). We used a blend composition of 1 part Acr-Sil to 1 part Epo by volume, herein referred to as Blend 1:1. The type of sol has a marked effect on the rate and degree of Omnirad™ 784 consumption: for Epo sols, a plateau consumption of ~75% is observed after 1800 s, while for Acr-Sil and Blend 1:1 sols, no consumption plateau was reached during this same period of time. We attribute this lack of plateau to the higher starting concentration of Omnirad™ 784 in Acr-Sil and Blend 1:1 (10 mM in Acr-Sil vs 7 mM in Blend 1:1 vs 4 mM in Epo sol). The initial consumption of Omnirad™ 784 appears slightly above 0 mM (<0.1 mM) at 0 s due to a small (<1 s) delay between collecting a reference spectrum, starting the spectral measurement, and activating the halogen lamp source.

The initial rate of Omnirad™ 784 consumption was fitted to a pseudo-zero-order rate law to quantify and compare the photolysis rate of the photoinitiator in different sols over the first 150 seconds of irradiation. Over this period, linear consumption is observed for all samples (FIG. 17a, Table 1), indicating that the initiation process is rate-limited by the photon flux rather than the photoinitiator concentration of (FIG. 26). The initial rate was slightly higher for the Acr-Sil sol (3.84+0.33 μM s⁻¹) compared to the Epo sol (2.83+0.10 M s⁻¹). The difference in photolysis behavior between Acr-Sil and Epo sols is attributed to a higher percentage of photon absorption by Omnirad™ 784 in Acr-Sil, in which there is no competition with OPPI. We note that a control experiment showed that polymerization of Epo does not proceed in the absence of OPPI. Furthermore, the two systems undergo different polymerization mechanisms. It has also been previously reported that Omnirad™ 784 photolysis occurs via several intermediates within Epo sols, which could explain the slower kinetics. The lower rate in Epo could also originate from its greater acidity environment (pTHF is a proton donor), which will affect the protonation of Omnirad™ 784 and subsequent photolysis products.

TABLE 1
Photolysis parameters determined for Omnirad ™ 784 during
photopolymerization of Acr-Sil, Epo and Blend 1:1 sols, with and
without LV, under irradiation with the halogen lamp (0.63 mW cm⁻²).

| | | | Degree of | Degree of | |
|---|---|---|---|---|---|
| | k ^{a} | | Consumption | Consumption | Photoinitiation |
| Sample | (×10⁻⁶M s⁻¹) | R^{2 b} | (t = 150 s, %) ^{c} | (t = 1800 s, %) ^{d} | Yield ^{e} |
| Acr-Sil | 3.84 ± 0.33 | 0.971 | 5.4 | 86.3 | 2.89 ± 0.25 |
| Acr-Sil LV | 3.27 ± 0.21 | 0.984 | 5.8 | 57.3 | 2.46 ± 0.16 |
| Epo | 2.83 ± 0.10 | 0.995 | 13.1 | 76.2 | 2.46 ± 0.09 |
| Epo LV | 2.67 ± 0.06 | 0.998 | 13.2 | 70.1 | 2.32 ± 0.05 |
| Blend 1:1 | 2.38 ± 0.14 | 0.987 | 5.7 | 52.4 | 2.11 ± 0.12 |
| Blend 1:1 LV | 3.25 ± 0.23 | 0.980 | 7.3 | 52.4 | 2.88 ± 0.20 |

^{a} Pseudo zero-order rate constant and
^{b} goodness-of-fit for initial rates fit in linear region (0-150 s).
^{c, d} Normalized degree of consumption at 150 s and 1800 s.
^{e} Initiation yield - the number of moles of Omnirad ™ 784 consumed per mole of photons absorbed by Omnirad ™ 784. See Section 7.4, SI for calculation details.

A slower rate is observed for the Blend 1:1 sol (2.38+0.14 μM s⁻¹) than in homopolymer sols, contradicting the trend observed in the percentage of photon absorption by Omnirad™ 784, whereby we would expect the Blend 1:1 rate to lie between that of Acr-Sil and Epo. The photolysis kinetics of the blend cannot be easily deconvoluted into independent acrylate and epoxide elements, suggesting that there is some interaction between the photoinitiation processes for Acr-Sil and Epo.

Interestingly, the initial rate deviates for the sols upon adding LV (FIG. 3b), and the effect varies with sol composition. For Acr-Sil, Omnirad™ 784 consumption decreases slightly (to 3.27+0.21 μM s⁻¹), indicative of a slower photolysis rate, while for Epo sols, the rate is unaffected. Furthermore, the degree of consumption at t=1800 s in the Acr-Sil LV reveals a significant decrease in photolysis (86.3% cf 57.3%), while the Blend 1:1 and Epo sols remain unchanged. Our calculations show that adding a luminophore results in competition for photon absorption, with 34% of photons absorbed by LV in both sols (Table S1, SI). Photon competition explains the slower photolysis rate of Omnirad™ 784 in Acr-Sil sols upon adding LV. However, in Epo sols, a decrease in photolysis rate is not observed, suggesting that a photon absorbed by LV may also lead to consumption of an Omnirad™ 784 molecule.

A considerable increase in photolysis rate was observed for Blend 1:1 (from 2.38±0.14 μM s⁻¹ to 3.25+0.23 μM s⁻¹) upon the addition of LV, which was unexpected. This increase results in a concomitant rise in the photoinitiation yield (2.11+0.12 to 2.88+0.20) and a higher degree of consumption at 150 s (5.7% to 7.3%) for the Blend 1:1 LV. This demonstrates the anomalous behavior in the Blend 1:1 system, which differs from that observed in Acr-Sil and Epo sols and can no longer be described solely by photon competition, suggesting a secondary photolysis mechanism.

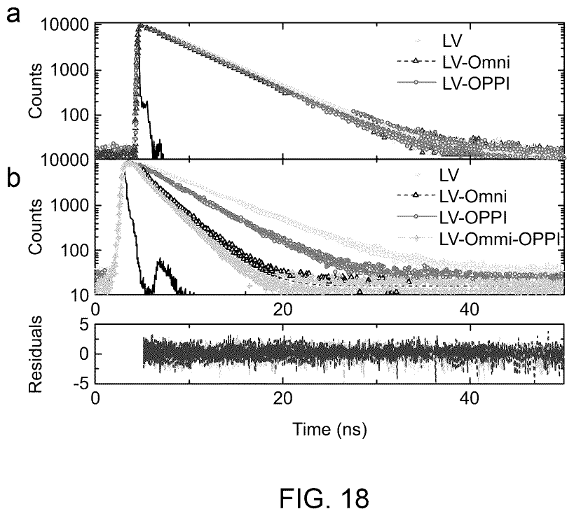

The potential interaction between LV, Omnirad™ 784 and OPPI was explored by time-resolved fluorescence quenching. All fluorescence decay curves were obtained using toluene as a solvent and could be fitted to a single exponential. At low luminophore concentration (5 μM in toluene), the fluorescence lifetime of LV (τ=4.6 ns) remains unchanged upon the addition of Omnirad™ 784 (200 M, τ=4.6 ns) or OPPI (550 μM, τ=4.6 ns) at similar molar ratios as those used in the polymer sols (FIG. 4a, Table S2, SI). This indicated an absence of fluorescence quenching at low luminophore concentrations. However, at higher LV concentration (300 μM in toluene), comparable to that used in polymer sols, a clear decrease in the fluorescence lifetime (τ=5.1 ns) was observed in the presence of either Omnirad™ 784 (10 mM, τ=2.3 ns) or OPPI (30 mM, τ=3.7 ns), (FIG. 18b, Table S2). This indicates that the Omnirad™ 784 photoinitiator quenches the LV fluorescence more effectively than the OPPI co-initiator, despite being present at significantly lower concentrations than OPPI. A solution containing both Omnirad™ 784 (10 mM) and OPPI (30 mM) shows a marginal increase in quenching, as shown by the fluorescence lifetime of τ=2.0 ns.

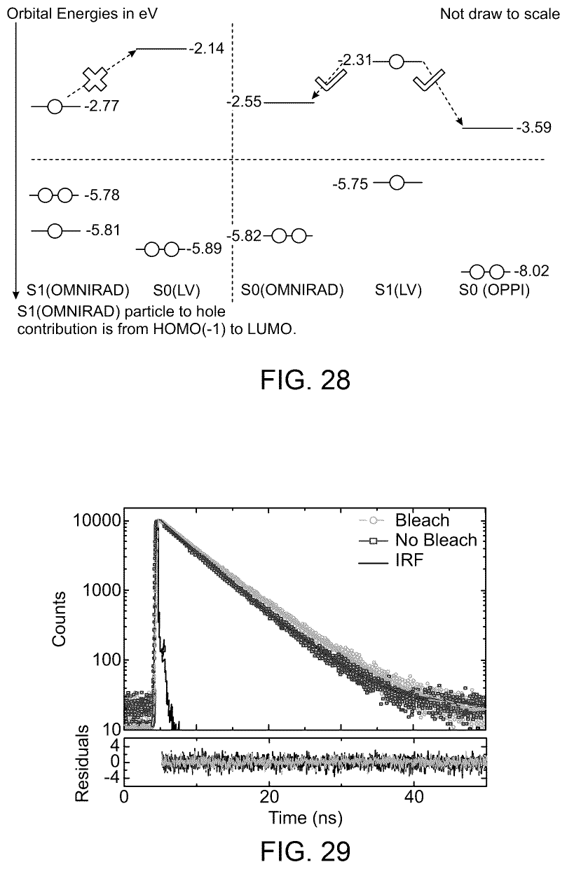

We therefore attribute this fluorescence quenching and the enhanced photoinitiation kinetics observed primarily to electron transfer from LV to Omnirad™ 784, as supported by density functional theory (DFT) simulations (see below). The DFT results demonstrate that reactions in which an electron is transferred from LV to Omnirad™ 784 are preferred in all cases. While the free energies obtained for the adiabatic species suggest all electron transfer reactions to be slightly endergonic (Table S3), consideration of the energy available upon photoexcitation (Table S4) suggests that electron transfer from the photoexcited LV to the ground state Omnirad™ 784 species is the lowest energy reaction and a feasible pathway, with a free energy of 1.63 kJ/mol falling within the limits of error in the calculations. Furthermore, all the calculations were performed at a temperature of 298 K and considering the increase in local temperature (up to ~150 °C) caused by photopolymerization, we expect the endergonicity of the electron transfer reactions to be further reduced. Finally, analysis of the HOMO-LUMO orbital energies further supports electron transfer from the photoexcited LV to Omnirad™ 784 as the most favorable mechanism (FIG. 28). As such, we postulate that at high concentrations of both LV and Omnirad™ 784, the intermolecular distance between both species is reduced such that electron transfer from the excited-state luminophore donor to the ground-state photoinitiator acceptor is preferred. The dependence on the intermolecular distance between the two species explains the lack of fluorescence quenching at low concentrations of LV. For the quenching mechanism of OPPI, any electron transfer process must involve its ground-state, since OPPI does not absorb at the excitation wavelength used (375 nm). Electron donation to ground-state iodonium salts has been frequently reported, triggering degradation of the phenyliodonium fragment into Ph• and PhI. DFT calculations on the excited state and the one-electron reduced and oxidized species of OPPI corroborate this mechanism. Analysis of the HOMO-LUMO energies (FIG. 28), show that electron transfer from the photoexcited LV to OPPI is possible, with a greater thermodynamic driving force than Omnirad™ 784. Therefore, based on the thermodynamic calculations and the concentrations used, the origin of the increased quenching observed for Omnirad™ 784 (FIG. 18) most likely lies in the kinetics of the electron transfer process.

In summary, luminophores play a non-innocent role when incorporated into photopolymer sols, often having a complex effect on the photopolymerization kinetics, as exemplified by Omnirad™ 784 and Lumogen® Violet. Our studies point towards electron transfer between the photoinitiator and luminophore as the cause. Therefore, monitoring the reaction in situ to reveal any differences is prudent.

Photolysis Kinetics within Patterned Polymer Blend Films

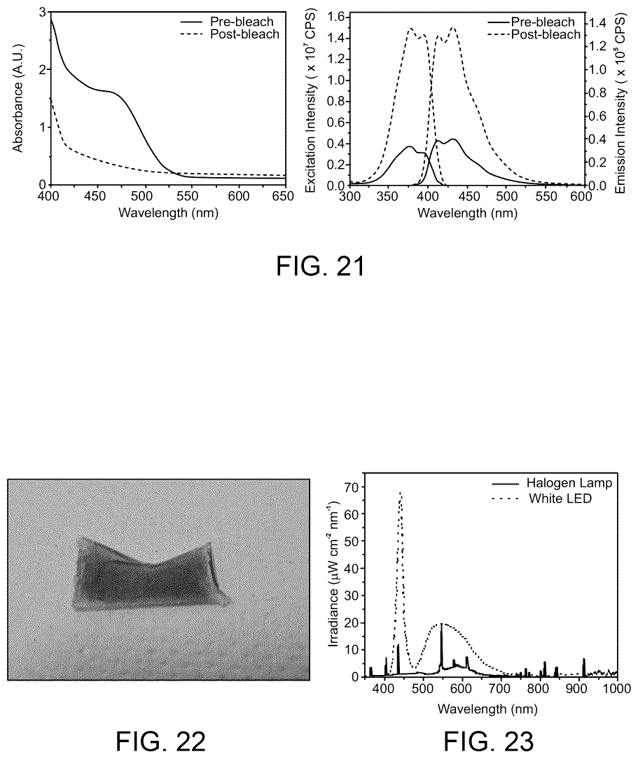

To translate our understanding of the photolysis kinetics in bulk samples to patterned WEL samples, a UV-Vis absorbance spectroscopy functionality was built into the fabrication setup, enabling waveguide formation to be monitored in situ (see below for further details). The ability to monitor the progress of polymerization is particularly advantageous, as WEL formation is likely affected by the incorporation of a luminophore. In situ monitoring also allows for the systematic and reproducible fabrication of samples using spectroscopic events as reference points rather than a simple timer. A collimated light source with a higher irradiance (>1 mW cm⁻²) was required for waveguide channel formation to be observed, primarily due to the implementation of the chrome photomask, which reduced the incident irradiance upon the sol by half (FIG. 21). As such, the halogen lamp used in the previous studies was replaced with a collimated white LED with adjustable irradiance up to 2.6 mW cm².

Polymer blends consisting of 3 parts Acr-Sil to 2 parts Epo by volume (herein referred to as Blend 3:2), either with (0.02 wt %) or without LV, were prepared and injected into 3D-printed sample cells. The 3:2 composition was chosen because it had a lower amount of glass adhering Epo component than a 1:1 blend, making it easier to separate WELs from glass slides. Samples were loaded into the fabrication setup (see FIG. 21) and illuminated by the white LED beam for 10 minutes at an irradiance of 1.4 mW cm⁻² A representative micrograph of the obtained LWEL films is shown in FIG. 5a. We note that there was no measurable difference in the spatial resolution between WELs made with and without LV.

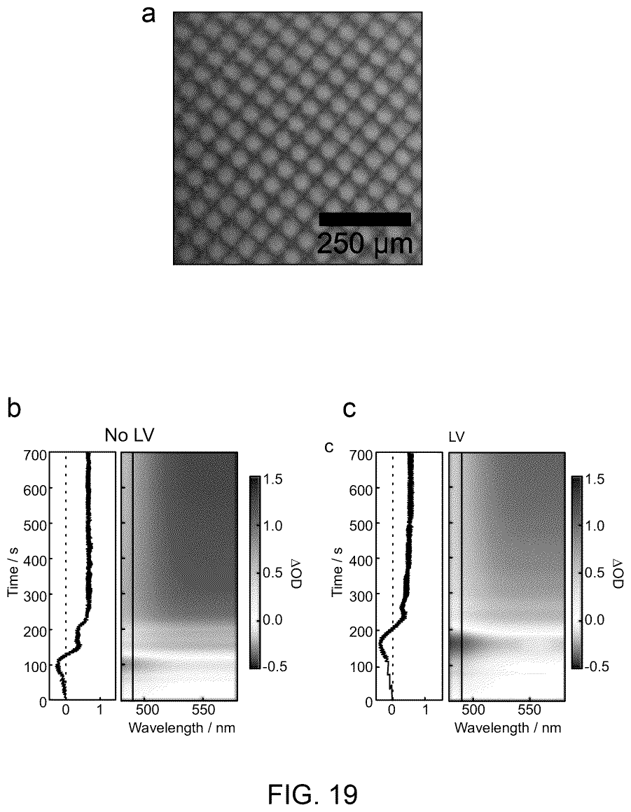

The change in optical density (ΔOD) of LWEL films during photopolymerization was monitored with irradiation time. Monitoring was carried out across the wavelength range 480-580 nm via in situ absorbance spectroscopy. Over this wavelength range, both the consumption of Omnirad™ 784 and the formation of waveguide channels were detectable. In the absence of LV, the spectral map shows an initial induction period of ~100 s before any significant changes in transmission are observed (FIG. 19b). An increase in the transmission is evident below 500 nm after 100 s, consistent with the depletion of Omnirad™ 784, as observed for the bulk samples. This induction period is related to the change in probe light geometry used for UV-Vis absorbance spectroscopy measurements on bulk and patterned blends. For (L)WEL samples, the excitation and probe source are the same, meaning the excitation irradiance is non-uniform and drops exponentially with the pathlength. An increase in the transmittance is seen when enough Omnirad™ 784 is depleted across the pathlength such that light exits the sol and reaches the spectrometer. After 200 s, scattering losses become more pronounced, manifesting as an increase in optical density (OD). We attribute the scattering losses to the formation of waveguide channels, as this behavior was not observed in blends without waveguide patterning.

The addition of LV shifts the peak in Omnirad™ 784 consumption from t=100 s to t=150 s and results in more Omnirad™ 784 being consumed (apparent from the more considerable increase in transmission, FIG. 19c), as seen in bulk samples. Furthermore, the increased scattering at later times is less pronounced upon addition of LV, which may be indicative of slight changes in refractive index contrast between the waveguide channels and their surroundings induced by the photoinitiator-luminophore interaction.

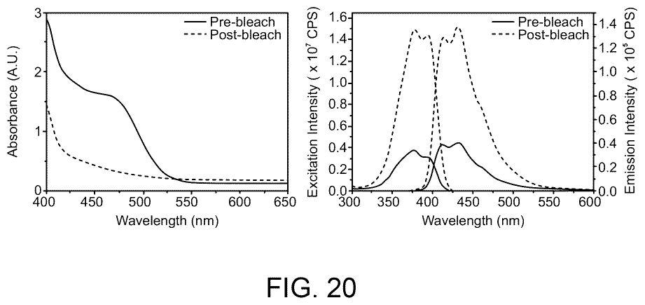

The in-situ absorbance measurements also reveal that not all photoinitiator is consumed during the reaction. Remaining Omnirad™ 784 was removed by irradiating the sample with a white LED (2.5 minutes at 53 mW cm⁻² irradiance), in conjunction with a long pass filter (495 nm) to prevent luminophore photodegradation. Our results show the disappearance of the Omnirad™ 784 shoulder (see FIG. 20a) post-bleaching and a 4-fold increase in fluorescence counts (FIG. 20b). We note that control measurements on a sample without LV exhibited negligible fluorescence over the same wavelength range, which excludes Omnirad™ 784 as a source of fluorescence. Hence, the observed increase in fluorescence intensity is accounted for by the decrease in parasitic absorption from Omnirad™ 784 and a decrease in electron transfer from the luminophore to the photoinitiator.

The emission decay behavior of LV in LWELs pre- and post-bleaching was also investigated. In contrast to the earlier studies in solution, the decay curves were best modelled by a double-exponential decay, indicating the presence of two distinct luminophore environments (see Table S2). The major component has a lifetime, t₁~5 ns (f₁~90%), that is comparable to the natural lifetime of LV in toluene at low concentration. The secondary component has a lifetime t₂ 2 ns (f₂-10%), which is similarly in excellent agreement to the quenched lifetime of LV in toluene at high concentration in the presence of Omnirad™ 784/OPPI. In contrast to solution, in the solid LWEL films diffusion is negligible on the timescale of this measurement, enabling both contributions to be resolved. Interestingly, f₂ decreases to 5.0% following photobleaching, confirming the luminophore-photoinitiator interaction observed previously, which disappears as the photoinitiator is depleted. As the interaction between Omnirad™ 784 and LV is reduced upon bleaching, this leads to a higher fraction of emissive luminophore species, further supporting the increased fluorescence intensity of the LWEL samples upon photoinitiator bleaching.

### Supporting Information

The following supporting information is given in connection with the above-described Examples—Section 2 examples.

### Materials

All chemicals and reagents were purchased from commercial suppliers and used as received. 3-(trimethoxysilyl)propyl methacrylate (MAPTMS, 98%), hydrochloric acid (HCl, ACS reagent grade, 37%), 3,4-epoxycyclohexylmethyl 3,4-epoxycyclohexanecarboxylate (EEC, 90%) and poly(tetrahydrofuran) (pTHF, Mₙ=250 g mol⁴) were purchased from Sigma Aldrich. Epoxypropoxypropyl terminated polydimethylsiloxane (pPDMS, MW=363 g/mol, 90%) was purchased from Gelest Inc. The photoinitiator [(bis(η5-cyclopentadienyl) bis(2,6-difluoro-3-(1H-pyrrole-yl)-phenyl) titanium (IV)](Omnirad™ 784, 99%) was purchased from IGM Resins. The co-initiator 4-octyloxyphenyl phenyliodonium hexafluoroantimonate (OPPI) was kindly donated by Hampford Research Inc. The luminophore 2-(2-ethylhexyl)-6,7-dimethoxy-1H-benzo[de]isoquinoline-1,3(2H)-dione (Lumogen® Violet) was procured from BOC Sciences.

### Precursor Sol Preparation

### Preparation of Methacrylate-Substituted Siloxane Sol

Methacrylate-substituted siloxane sols were prepared through two-step acid-catalyzed hydrolysis and condensation of MAPTMS. First, 0.05 μM HCl (0.30 g) was added to MAPTMS (4.89 g, 0.0197 moles) yielding a two-phase mixture which transformed into a homogenous, transparent, colorless liquid after stirring at room temperature (RT) for 15-20 min (Sol 1, FIG. 15). The titanocene-based free-radical photoinitiator Omnirad™ 784 was then added to the sol (0.5 wt %), along with Lumogen® Violet (0.02 wt %) if using. The mixture was protected from ambient light with aluminum foil wrapping and left to stir for six days at room temperature (RT).

### Preparation of Multicomponent Epoxide Sol

The epoxide sol (Sol 2, FIG. 15) was prepared following a previously reported method with the photoinitiator (camphorquinone) substituted by Omnirad™ 784 and the proton donor (benzyl alcohol) substituted by pTHF.¹ EEC (51 wt %), pPDMS (26 wt %), pTHF (20 wt %) Omnirad™ 784 (0.2 wt %) and OPPI (2.0 wt %) were mixed in a single pot until homogeneous. Lumogen® Violet was added at a 0.02 wt % loading if using. The mixture was protected from ambient light with aluminum foil wrapping and left to stir at room temperature for at least 48 hours before use.

### Preparation of Polymer Blends

Precursor blends were created by mixing the methacrylate-substituted siloxane sol and the component epoxide sol at the required ratio under stirring for 30 min at RT to ensure homogenous mixing. Herein, references to the composition of the photosensitive blends will be made by the volume ratio of the amount of acrylate to epoxide (i.e., blend 3:2 refers to a formulation with 3 parts methacrylate-substituted siloxane to 2 parts epoxide).

### Photopolymerization Conditions

### Bulk Homopolymers and Blends

Bulk polymer samples were fabricated by vertical irradiation of the liquid sol contained in an Eppendorf UVette® with an MRL-58 multiple ray lamp, with a cool white halogen tube as the light source (0.63 mW cm⁻²) for an irradiation period between 10 to 30 minutes. Samples appeared solid after irradiation with partial discoloration due to photobleaching of Omnirad™ 784.

### Optical Setup for LWEL Film Fabrication

To fabricate LWEL films, an optical setup was built with the ability to monitor the fabrication process in situ by UV-Vis absorbance spectroscopy (see FIG. 21). All optical components were mounted on a dovetail rail (Thorlabs RLA600/M). A white LED (Thorlabs MCWLH7) was collimated by a lens (f=32 mm, Thorlabs SM2F32-A), and the size of the illuminated region was controlled using an adjustable iris (Thorlabs ID50/M). An LED driver (Thorlabs LEDDIB) enabled the irradiance to be adjusted up to 2.6 mW cm⁻². A custom chrome photomask (Micro Lithography Services) with a 40 μm by 40 μm grid pattern (A=80 μm) was used to block light from propagating in certain regions of the sample cell. Transmitted light was then collimated by a lens (f=150 mm, Thorlabs AC508-150-A-ML) and 50/50 beamsplitter cube (Thorlabs BS031) used to capture an image with its associated spectrum simultaneously. A lens (f=75 mm, Thorlabs AC508-075-A-ML) was used to focus the light onto a CMOS chip (Thorlabs Zelux 1.6 MP) allowing live experimental capture. A fiber collimation package (f=7.86 mm, Thorlabs F240SMA-532) was used to transport light to a spectrometer (Ocean Optics Flame). Neutral density filters (Thorlabs NE2R0XA series) were used to decrease the power in both the camera and spectrometer. A Python script was written to interface with the spectrometer and CMOS chip, enabling time-stamped images and spectra to be collected regularly.

The precursor sol (homopolymer or blend) was injected into a custom-designed sample cell consisting of a 3D-printed thermoplastic polyurethane (TPU) spacer sandwiched between two glass slides. The TPU spacer was printed to a thickness of 1 mm with an Ultimaker3 3D printer. Silicon sealant was used to form a liquid-tight seal with glass slides. Samples were irradiated by a collimated White LED beam for 10 minutes with an irradiance behind the mask of 1.4 mW cm⁻² (measured by a Thorlabs S120VC photodiode). On removal, samples were solid and appeared hazy due to waveguide lattice formation.

### Removal of Unreacted Photoinitiator

Unreacted Omnirad™ 784 was removed from LWEL films by irradiating with a high-power white LED array (Brennenstuhl JARO 7003 μM, irradiance=53 mW cm⁻²). LWEL films were covered with a long pass filter (495 nm) and irradiated for 2.5 minutes.

### Spectroscopic Characterization

### UV-Vis Absorbance Spectroscopy

UV-Vis absorbance spectra were recorded on a Perkin Elmer Lambda 750 spectrophotometer. The spectra were collected using a wavelength scan method with a slit width of 2 nm and a step size of 1 nm. For solution samples, spectra were collected using a 10 mm quartz cuvette (Hellma) and measured against a solvent reference. For solid (bulk) samples, spectra were measured against air as the reference.

### Steady-State Photoluminescence (PL) Spectroscopy

A Horiba Jobin Yvon Fluorolog-3 fluorescence spectrometer was used to record photoluminescence excitation and emission spectra. The entrance and exit slits were adjusted to obtain a maximum PL intensity in the region of interest while maintaining it within the area of linear response. The integration time was 0.1 s. Emission spectra were corrected using the radiometric correction factors supplied by the manufacturer.

### Time-Resolved Emission Spectroscopy

Photoluminescence decay measurements were performed using the time-correlated single photon counting method (TCSPC) on an FLS1000 PL spectrometer (Edinburgh Instruments). The excitation source was a pulsed laser of wavelength 375 nm (EPL-375, pulse width <100 ps, pulse frequency 20 MHz). The emission decay was recorded at 430 nm using a high-speed photomultiplier tube (HS-PMT-920, 200 ps response time) or visible photomultiplier tube (PMT-980, 600 ps response time) with TCC2 counting electronics. Deconvolution and data-fitting were performed as individual fits to each emission decay using a single or double exponential decay function from 5-50 ns using the FAST software package (Edinburgh Instruments). The fit quality was assessed using reduced chi-square statistics, χ², and the statistical randomness of the residuals.

### Time-Dependent Absorbance Spectroscopy to Monitor Photopolymerization

To monitor the reaction kinetics, the consumption of the photoinitiator Omnirad™ 784 was measured by time-resolved UV-Vis absorbance spectroscopy. Unirradiated components were loaded into an Eppendorf UVette® (2 mm path length) with a transmission range between 220-1600 nm and subjected to irradiation from above. Spectra were collected at 30-second intervals using an Ocean Optics Flame spectrometer, together with an Ocean Optics DH-2000 white light source, and the absorbance was converted to a concentration by the Beer-Lambert law. The concentration was calculated from the average absorbance in the wavelength range of 450 nm to 455 nm, coinciding with one of the absorbance maxima of Omnirad™ 784.

### Computational Simulations

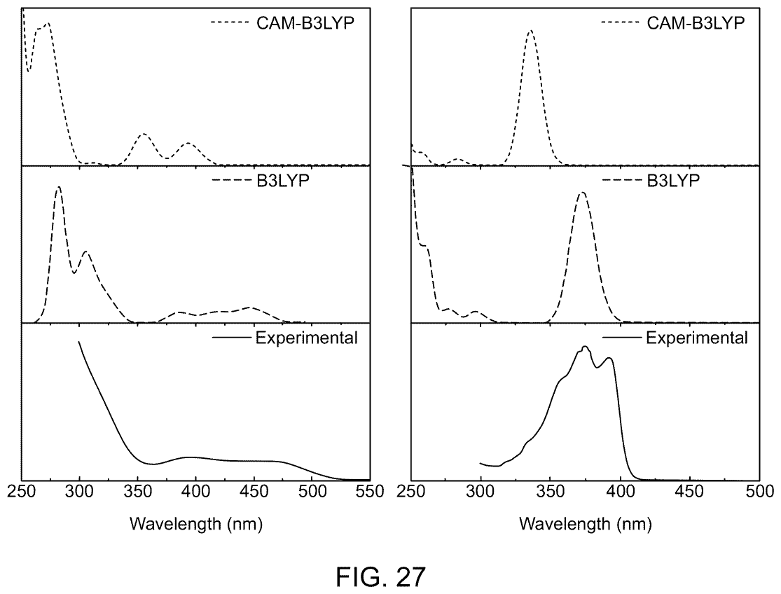

Density functional theory (DFT) calculations were performed using Orca 5.0. All ground-state structures were confirmed to be minimum-energy arrangements via analytic hessian computations, displaying positive curvature along all vibrational modes. The excited states were modelled by linear response time-dependent (TD) DFT, with the nature of the stationary point validated by numerical hessian computations (±5×10⁻³ Bohr increments). The hybrid exchange-correlation functional B3LYP was used in conjunction with the Karlsruhe valence triple-(polarized basis set, def2-TZVP. The CAM-B3LYP functional was also tested and was found to give a poorer agreement to experiment (see FIG. 27). The external reaction field was modelled by the inclusion of a dielectric continuum model, specifically the conductor-like polarizable continuum model (CPCM).¹³ A dielectric constant of 2.4 (toluene) was used. The adiabatic reaction energies are given with respect to electronic (E) and free energies (G), the later calculated through the standard ideal gas, rigid rotor, and harmonic oscillator statistical models and at a temperature of 298.15 K.

### Polymerization Mechanisms

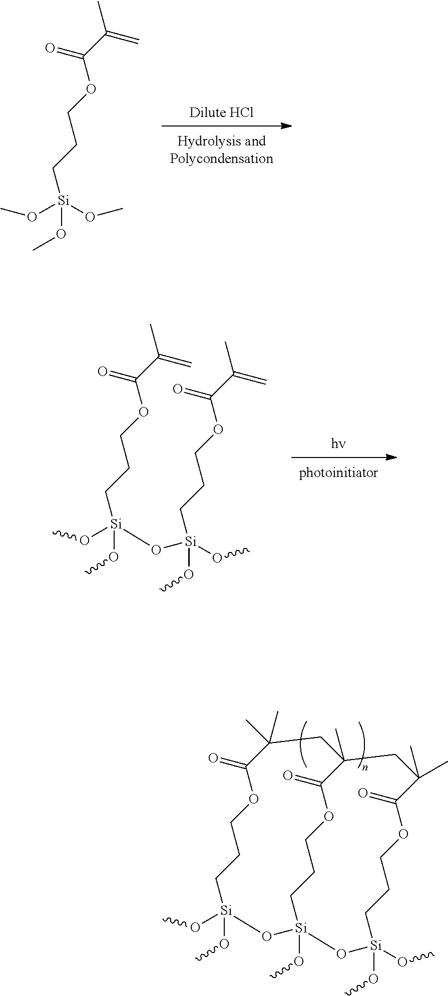

Scheme S1|Polymerization mechanism for MAPTMS (Sol 1) consisting of an initial acid-catalyzed hydrolysis-condensation reaction to form the siloxane network, followed by photoinitiated free-radical polymerization of the methacrylate groups.

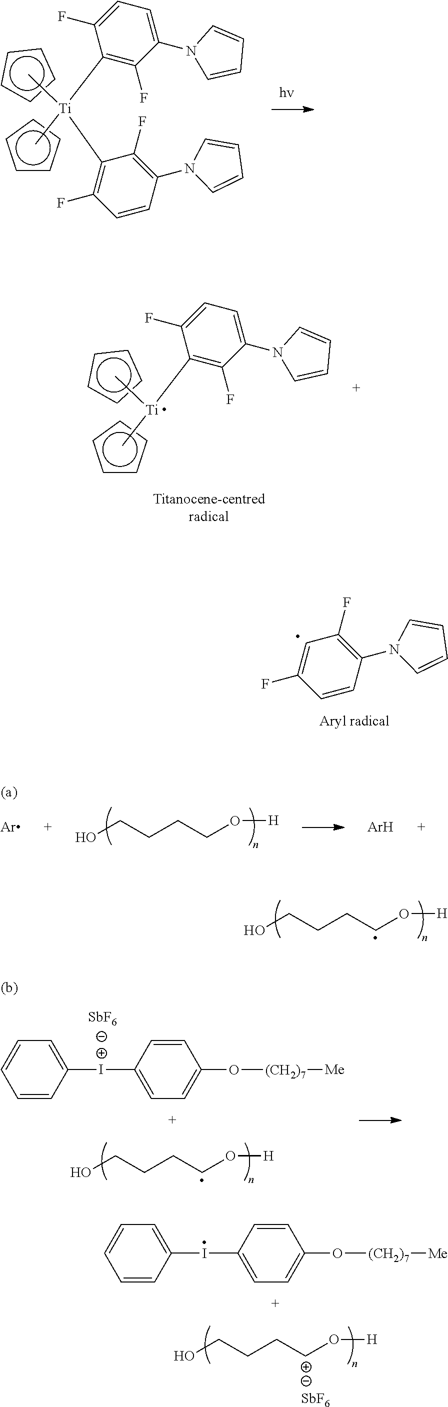

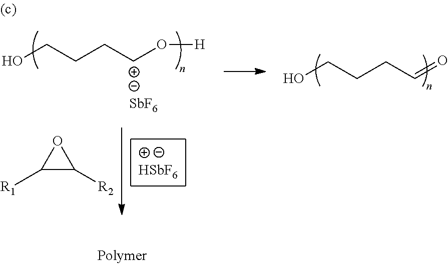

Scheme S2|Free-radical promoted cationic polymerization mechanism for component epoxide sol (Sol 2). (a) Irradiation of Omnirad™ 784 results in forming aryl- and titanium-centered radicals. The polyTHF hydrogen donor undergoes hydrogen-abstraction by the aryl radical. (b) The resulting α-hydroxyalcohol radical reacts with the OPPI aryliodonium to give an iodine-centered radical and an α-hydroxyalcohol cation. (c) The α-hydroxyalcohol cation spontaneously deprotonates, resulting in an aldehyde and a hexafluoroantimonate superacid capable of initiating epoxide polymerization. All radical species generated throughout the process can catalyze the photoinitiation reaction.

### Supplementary Experimental Data

Photolysis Kinetics in Bulk Homopolymers and their Blends

The photolysis kinetics during photopolymerization of bulk Acr-Sil, Epo and Blend 1:1 sols were studied by following the consumption of Omnirad™ 784 by time-resolved UV-Vis absorbance spectroscopy. Acr-Sil sols showed a considerable increase in scattering as the polymerization proceeded, manifesting as a linear absorbance feature above 550 nm (FIG. 24a). We attribute this feature to the formation of micron-sized nuclei as the addition polymerization of methacrylate groups proceeds. To correct for scattering, the Acr-Sil spectra were subtracted by the average absorbance in the wavelength range 575-600 nm, where no absorbance change due to Omnirad™ 784 consumption is expected (FIG. 24b). This scattering correction was unnecessary for Epo and Blend 1:1 samples.

Molar absorbance coefficients, c, for Omnirad™ 784 in each sol were determined using a known photoinitiator concentration using the average absorbance over the wavelength range 450-455 nm. This wavelength range was selected to ensure Omnirad™ 784 as the sole absorbing species while maintaining a high absorbance coefficient. The values obtained were: ε_{Acr-Sil}=711 M⁻¹ cm⁻¹, ε_{Epo}=1,213 M⁻¹ cm⁻¹ and ε_{Blend(1:1)}=893 μM⁻¹ cm⁻¹ (see FIG. 25). Once the molar absorbance coefficients were calculated, the molar degree of consumption of Omnirad™ 784 could be computed from time-dependent UV-Vis absorbance spectra. The obtained concentration profiles were also normalized to the starting concentration of Omnirad™ 784 to give a conversion (%) profile (see Table 1).

The initial rate of photolysis for the different sols was calculated from the slope of the linear curve of the molar consumption of Omnirad™ 784 in the range of 0-150 sec (see FIG. 3, Table 1, main paper), according to a pseudo-zero-order reaction rate. Further tests confirmed that under identical irradiation conditions, at a lower Omnirad™ 784 concentration (0.05 wt %, 1 mM), the photoinitiator concentration limits the reaction and proceeds under pseudo-first-order conditions (see FIG. 26).

### Calculation of the Initiation Yield

The initiation yield is the moles of Omnirad™ 784 consumed per mole of photons absorbed by Omnirad™ 784. The moles of incident photons (N_{incident}) can be calculated based on spectral power (I) and wavelength (λ):

$${N}_{incident} = \frac{I}{{E}_{ph}} = \frac{I λ}{{N}_{A} hc} \qquad Eq 1$$

The local volumetric rate of photon absorption (LVRPA) can then be calculated based on N_{incident} and the absorbance of Omnirad™ 784 (Abs).

$$L V R P A = N ( 1 - 1 {0}^{- Abs} ) = \frac{1}{{N}_{A} hc} λ ( 1 - 1 {0}^{- Abs} ) I \qquad Eq 2$$

where Abs can be calculated using the wavelength-dependent absorbance coefficient (ε(λ)), concentration (c) and path length (l), i.e. Beer-Lambert law:

Abs=ε(λ)cl Eq 3

For a broadband lamp spectrum, we sum over all emitted wavelengths:

$$L V R P A = \frac{1}{{N}_{A} hc} {\sum }_{λ} λ ( 1 - 1 {0}^{- Abs ( λ )} ) I ( λ ) \qquad Eq 4$$

The lamp or LED spectra (I(λ)) used in this calculation is shown in FIG. 23. The absorbance coefficients (ε(λ)) used in this calculation are shown in FIG. 2 (main text). The absorbance was calculated with a path length (l) of 1 cm and the starting concentration of Omnirad™ 784 (c) in each sol (Table S1).

The initiation yield (Y) is then given by the Omnirad™ 784 consumption rate (k) divided by the LVRPA.

$$Y = \frac{k}{L V R P A} \qquad Eq 5$$

### Time-Resolved Fluorescence Quenching Studies on LV Solutions

Time-resolved fluorescence decay curves were fitted to an exponential decay model:

$$I ( t ) = {\sum }_{i}^{n} {α}_{i} exp ( - t / {τ}_{i} ) \qquad Eq 6$$

where I(t) is the photoluminescence intensity as a function of time, t, normalized to the intensity at t=0, αᵢ is the pre-exponential factor of the component and τᵢ is the lifetime of the iₜₕ decay component. The fractional contribution is given by:

$${f}_{i} = \frac{{α}_{i} {τ}_{i}}{{\sum }_{j}^{n} {α}_{j} {τ}_{j}} \qquad Eq 7$$

For LV solutions in toluene containing no quencher, Omnirad™ 784 or OPPI, a single exponential decay (n=1) yielded a good fit. For LWEL samples, pre- and post-bleach, a bi-exponential decay (n=2) was required. The quality of the fit was evaluated by the χ2 value and the randomness of the residuals.

TABLE S2
Lifetimes obtained from single-exponential fits to decay
curves for LV solutions in toluene in the absence and presence
of different quenchers. All decay curves are well-described
by a single exponential decay. Decay curves obtained with
excitation at 375 nm and emission at 430 nm.

| Sample | τ (ns) | Δτ (ns) | χ² |
|---|---|---|---|
| LV (5 μM) | 4.646 | 0.0001 | 1.088 |
| LV (5 μM) + Omnirad ™ (200 μM) | 4.612 | 0.0001 | 1.076 |
| LV (5 μM) + OPPI (550 μM) | 4.577 | 0.0001 | 1.104 |
| LV (300 μM) | 5.096 | 0.0002 | 1.239 |
| LV (300 μM) + Omnirad ™ (10 mM) | 2.252 | 0.0007 | 1.214 |
| LV (300 μM) + OPPI (30 mM) | 3.669 | 0.0003 | 1.160 |
| LV (300 μM) + Omnirad ™ | 1.975 | 0.0009 | 1.274 |
| (10 mM) + OPPI (30 mM) | | | |

### Computational Results

The B3LYP functional was selected as it gave better agreement to experimental spectra (FIG. 27). The broad absorption band of Omnirad™ 784, located between approximately 370 and 480 nm, consists of three states, S1 (448.6 nm), S5 (416.5 nm) and S7 (385.1 nm), all with oscillator strengths marginally greater than 0.01 and are of ligand-to-metal charge transfer character. On the other hand, the Lumogen® Violet spectrum is dominated by a single peak, S1 (372.6 nm), with an oscillator strength of 0.41 and is of ππ* character.

Following Kasha's rule, the electron transfer reaction energetics were computed with respect to the S1 state of either Omnirad™ 784 or Lumogen® Violet. The feasibility of electron transfer reactions was investigated from a thermodynamic viewpoint under both adiabatic and vertical transition conditions, as well as through the analysis of the HOMO-LUMO energies of Omnirad™ 784 and LV.

Under adiabatic conditions (Table S3) all electron transfer processes are endergonic; however, the endergonicity is much lower for reactions involving electron transfer from LV to Omnirad™ 784 (Table S3, entries 1 and 3). Reactions involving photoexcited Omnirad™ 784 are in direct competition with the formation of aryl- and titanium-centered radicals (see Scheme S2) which was found to be extremely exergonic (−223 kJ mol¹).

The vertical transitions, directly after photoexcitation and before the photoexcited species have time to fully relax, were also investigated (Table S4), as this may offset the endergonicity. To mimic this, the free energy correction of the S₀ state was added to the electronic energy of the (vertical) excited state (S₁), which was then used to compute the thermodynamic reaction energy. In this case, the electron transfer from the photoexcited LV(S_{1,vert}) to the ground state Omnirad™ 784 (S₀) has the lowest endergonicity (1.63 kJ/mol), which is well within the limits of error in typical DFT calculations and could mean that this is a feasible pathway. This is the same reaction of low energy as previously seen (adiabatic calculations, Table S₃).

Therefore, from a thermodynamic viewpoint, it is likely that the LV acts as the photosensitizer, which is further strengthened by the larger oscillator strengths or the low-energy bands of each species. After photoexcitation, this species would donate an electron to Omnirad™ 784, while photoexcitation of Omnirad™ 784 would likely result in photocleavage.

TABLE S3
Adiabatic (ad) reaction energies for electron transfer
between LV and Omnirad ™ 784.

| | Electronic | Free |
|---|---|---|
| | Energy | Energy |
| Reaction | (kJ/mol) | (kJ/mol) |
| LV(S_{1, ad}) + Omnirad(S₀) → LV⁺ + | 32.98 | 27.42 |
| Omnirad⁻ | | |
| LV(S_{1, ad}) + Omnirad(S₀) → LV⁻ + | 123.38 | 112.27 |
| Omnirad⁺ | | |
| LV(S₀) + Omnirad(S_{1, ad}) → LV⁺ + | 106.13 | 8.45 |
| Omnirad⁻ | | |
| LV(S₀) + Omnirad(S_{1, ad}) → LV⁻ + | 196.52 | 93.30 |
| Omnirad⁺ | | |

TABLE S4
Vertical reaction energies for electron transfer
between LV and Omnirad ™ 784.

| | Electronic | Free |
|---|---|---|
| | Energy | Energy |
| Reaction | (kJ/mol) | (kJ/mol) |
| LV(S_{1, vert}) + Omn(S₀) −> LV⁺ + Omn⁻ | 19.30 | 1.63 |
| LV(S_{1, vert}) + Omn(S₀) −> LV⁻ + Omn⁺ | 109.69 | 86.48 |
| LV(S₀) + Omn(S_{1, vert}) −> LV⁺ + Omn⁻ | 73.62 | 55.95 |
| LV(S₀) + Omn(S_{1, vert}) −> LV⁻ + Omn⁺ | 164.01 | 140.80 |

Finally, investigation of the HOMO-LUMO energies of Omnirad™ 784 and LV (FIG. 28) shows a disfavored electron transfer from the photoexcited Omnirad™ 784 to LV, while electron transfer from the excited LV to the LUMO of the ground state Omnirad™ 784 is favored. This further supports the previous findings that the most likely electron transfer mechanism occurs from an excited-state LV to a ground state Omnirad™ 784.

### Conclusions

The relationship between luminophore-photoinitiator interactions and the photolysis kinetics during photopolymerization of methacrylate-siloxane- and epoxide-homopolymers and their blends as model systems has been examined. Initial rates analysis of the photoinitiator consumption revealed differences in the photolysis rates for all bulk polymer systems in the absence and presence of LV, with a notable (~40%) rate increase observed for Blend 1:1. Interpretation of these rates is highly complex since LV, Omnirad™ 784 and OPPI all compete for photon absorption in the emission region of the irradiation source, to an extent that is determined by the relative concentration and absorbance coefficient of each species and the photon flux at a given wavelength. However, fluorescence lifetime studies revealed that Omnirad™ 784 is the primary quenching species in this system, with DFT calculations supporting electron transfer from photoexcited LV to Omnirad™ 784 as the probable quenching process. This pathway provides a secondary mechanism by which the photoinitiator free radical species may be generated, leading to an acceleration in the photolysis rate and an increased degree of consumption of the photoinitiator. However, as the rate of electron transfer process will be highly dependent on the proximity of the two species, the absolute concentration and fluidity of the medium are also important. In-situ UV-Vis absorbance spectroscopy to monitor Omnirad™ 784 consumption during WEL formation further indicates that LV-photoinitiator interactions determine the photopolymerization kinetics, and provides an additional method to confirm channel formation through the observation of scattering. Notably, the results demonstrate that the photoinitiator is not completely consumed by the time the WEL channels are formed. Retention of the photoinitiator within the final LWEL is highly undesirable as it may lead to photodegradation of the luminophore during use. We have shown that the unconsumed photoinitiator can be removed using a simple post-fabrication irradiation protocol, which further leads to a fluorescence enhancement as the electron transfer pathways are eliminated.

### Clauses

The invention is now described with reference to the following preferred clauses:

1. A method for designing and preparing a thin luminescent polymer film, herein referred to as luminescent waveguide-encoded lattices (LWELs), that can expand the angular collection of incident light and spectrally tuning incident light to better match the absorption profile of an underlying PV cell comprising the following process:
(a) Enhancement of PV cell performance by LWELs by certain working principles.
(b) Fabrication process.
   2. A method for designing and preparing thin luminescent waveguide-encoded lattices (LWELs) according to claim 1, wherein the enhancement of PV cell performance by LWELs comprises the following working principles:
(a) Self-trapping of light by the polymer host. (b) Luminescence downshifting by the luminophore(s), (c) Patterning of selected waveguide geometries.
   3. A method for designing and preparing a thin luminescent waveguide-encoded lattices (LWELs) according to claim 2, wherein the self-trapping of light of polymer host is achieved by a photoinitiated polymerisation process comprising of a titanocene-based photoinitiator.
   4. The host polymer of method of claim 3 has high refractive index contrast (Δn>0.001).
   5. A method for designing and preparing thin luminescent waveguide-encoded lattices (LWELs) according to claim 2, wherein luminescence downshifting by the luminophore(s) is achieved by choosing luminescent material.
   6. The material of method of claim 5, wherein the luminescent material, comprising: an acrylate-epoxy composite of ratio 1:1, 2:1, 3:1, 3:2, 2:3, or 1:2, doped with Lumogen Violet luminophore up to 0.05% wt loading.
   7. The material of method of claim 5, wherein the luminescent material has high absorption coefficient, high transmittance and emits fluorescence at wavelengths where the PV cell have good quantum efficiency, high PLQY, and long-term thermal stability and photostability.
   8. A method for designing and preparing thin luminescent waveguide-encoded lattices (LWELs) according to claim 1, wherein the fabrication process of the luminescent polymer film is done by injecting a photosensitive sol into a transparent ring cell.
   9. The material of method of claim 8, wherein the photosensitive sol consists of methacrylate and epoxide monomers.
   10. A method for the preparation of methacrylate for photosensitive sol, according to claim 9, comprising the steps of:
(a) preparing a two-phase mixture by adding 0.30 g of 0.05 M hydrochloric acid to 4.89 g of MAPTMS, after stirring for about 15 to 20 minutes, changes into a homogenous, transparent colorless liquid.
(b) sensitizing the said mixture to light by adding 0.5 wt % of a free-radical photoinitiator.
(c) adding Luminophores to the said mixture at a 0.01-0.1 wt % loading.
(d) protecting the said mixture from ambient light and left to stir for 6 days before use.
   11. A method for the preparation of epoxide for photosensitive sol, according to claim 9, comprising the steps of:
(a) adding 3,4-epoxycyclohexylmethyl 3,4-epoxycyclohexanecarboxylate (‘EEC’), epoxypropoxy propyl terminate polydimethylsiloxane (‘pPDMS’), poly(tetrahydrofuran) (‘pTHF’), photoinitiator (e.g. Omnirad 784, IGM Resins) and 4-octyloxyphenyl) phenyliodonium hexafluoroantimonate (‘OPPI’) in 51%, 26%, 20%, 1.0%, and 2.0% by weight with sol mixture of 2.5 g, 1.3 g, 1.0 g, 0.050 g and 0.10 g, respectively, for a 4.95 g batch.
(b) adding Luminophores to the said mixture at a 0.01-0.1 wt % loading.
(c) protecting the said mixture from ambient light and left to stir for 2 days before use.
   12. The application of the method of claim 1 to enhance photovoltaic cell performance under indoor lighting for powering devices in the Internet-of-Things, enhance photovoltaic cell performance under outdoor lighting, particularly in cloudy weather (diffuse light) for residential solar panels, enhance photovoltaic cell performance under outdoor lighting, where sunlight is generally incident on the photovoltaic cell off-angle (i.e. at wide angles with respect to the photovoltaic cell surface normal), and to residential solar panels.

### REFERENCES

Ding N., Hosein I. D. Fluorescent Waveguide Lattices for Enhanced Light Harvesting and Solar Cell Performance//ACS Applied Energy Materials. 2023. Vol. 6. No. 12. pp. 6646-6655.
Tunstall-Garcia H. et al. Interplay of Luminophores and Photoinitiators during Synthesis of Bulk and Patterned Luminescent Photopolymer Blends//ACS Applied Polymer Materials. 2024.
Lawson T. et al. Luminescent waveguide-encoded lattices for light harvesting, https://www.nanoge.org/proceedings/HOPV23/63e4e0cc77da6e5d6fad10ce, March 2023
Luminescent Waveguide Encoded Lattices (LWELs) for Indoor Photovoltaics, https://gow.epsrc.ukri.org/NGBOViewGrant.aspx?GrantRef=EP/V048953/1
R. A. S. Ferreira et al., Mater. Today, 2020, 33, 105-121.

### M. Mitchell, M. Segev, Nature 1997, 387, 880.

S. Trillo, W. E. Torruellas, in Spatial Solitons, Vol. 82 (Eds: S. Trillo, W. Torruellas), Springer, Heidelberg, Berlin, Germany 2001, p. 87.
H. Buljan, M. Segev, M. Soljacić, N. K. Efremidis, D. N. Christodoulides, Opt. Lett. 2003, 28, 1239.
J. Zhang, K. Saravanamuttu, J. Am. Chem. Soc. 2006, 128, 14913.
I. D. Hosein et al., Adv. Funct. Mater., 2017, 27, 1702242.
Self-Trapping of Spatially and Temporally Incoherent White Light in a Photochemical Medium
Jihua Zhang, Kailash Kasala, Abhitej Rewari, and Kalaichelvi Saravanamuttu* JAC Communications, 2005
I. D. Hosein, H. Lin, M. R. Ponte, D. K. Basker, M. A. Brook, K. Saravanamuttu, Adv. Funct. Mater. 2017, 27, 1702242.
McKenna, B.; Evans, R. C. Towards Efficient Spectral Converters through Materials Design for Luminescent Solar Devices. Adv. Mater. 2017, 29 (28), 1606491. https://doi.org/10.1002/adma.201606491.
X. Huang, S. Han, W. Huang, X. Liu, Enhancing solar cell efficiency: the search for luminescent materials as spectral converters, Chem. Soc. Rev. 42 (2013) 191e192.
Lin, H., Hosein, I. D., Benincasa, K. A., Saravanamuttu, K. Adv. Optical Mater. 2019, 7, 1801091. DOI: 10.1002/adom.201801091
Lin, H., Benincasa, K. A., Fradin, C., Saravanamuttu, K., Advanced Optical Materials 2019, 7, 1801487. https://doi.org/10.1002/adom.201801487
Crivello, J. V. (2009), A new visible light sensitive photoinitiator system for the cationic polymerisation of epoxides. J. Polym. Sci. A Polym. Chem., 47: 866-875. https://doi.org/10.1002/pola.23203

1. A method of fabricating a thin luminescent polymer film having a patterned waveguide geometry, the method comprising:
the polymerisation of a photosensitive sol,
wherein the sol comprises at least one luminophore suitable for luminescence downshifting.

2. A method according to claim 1, wherein the photosensitive sol comprises a photoinitiator.

3. A method according to claim 2, wherein the photoinitiator is a transition-metal-based photoinitiator.

4. A method according to claim 3, wherein the photoinitiator is bis(η⁵-cyclopentandienyl) bis(2,6-difluoro-3-(1H-pyrrol-yl)-phenyl) titanium(IV).

5. A method according to claim 1, wherein the fabrication process comprises exposing the photosensitive sol to light.

6. A method according to claim 5, wherein the patterned geometry is achieved by exposing the photosensitive sol to light in said geometry.

7. A method according to claim 1, wherein the geometry is a radial geometry.

8. A method according to claim 1, wherein the luminophore is selected from the group consisting of polymeric or molecular conjugated organic materials, such as perylene, coumarin, naphthalimide, poly(fluorene), or benzothiadazole derivatives.

9. A method according to claim 1, wherein the luminophore is selected from:
1. 2-(2-ethylhexyl)-6,7-dimethoxy-1H-benzo[de]isoquinoline-1,3(2H)-dione (commercial name: Lumogen Violet);
2. N,N′-bis(2,6-di-tert-butylphenyl)perylene-3,4,9,10-bis(dicarboximide) (commercial name: Lumogen Orange);
3. 9-(Trifluoromethyl)-2,3,6,7-tetrahydro-1H,5H,11H-pyrano[2,3-f]pyrido[3,2,1-ij]quinolin-11-one (commercial name: Coumarin 153);
4. N,N′-bis(2,6-diisopropylphenyl)-1,6,7,12-tetraphenoxyperylene-3,4:9,10-tetracarboxdiimide (commercial name: Lumogen Red); or
5. 3,9-bis(2-methylpropyl) 4,10-dicyanoperylene-3,9-dicarboxylate (commercial name: Lumogen Yellow.

10. A method according to claim 1, wherein the sol comprises epoxide monomers and acrylate monomers.

11. A method according to claim 1, wherein the sol comprises:
p-PDMS;
EEC; and
an ingredient comprising a polymer structure having the following formula: 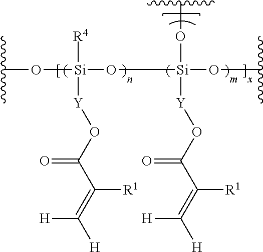
wherein
R¹ is H or alkyl;
Y is a linking group;
R⁴ is H, OH, or an alkyl or an alkoxy group;
x is an integer from 2 to 70;
n and m are independently selected as a fraction from 0 to 1, where n+m=1; and
R¹, R⁴, and Y may at each occurrence be the same or different.

12-17. (canceled)

18. A thin luminescent polymer film obtained or obtainable by a method according to claim 1.

19. (canceled)

20. An apparatus comprising:
a photovoltaic (PV) cell; and
a film as defined in claim 18.

21. (canceled)

22. A method according to claim 1, wherein the thin luminescent polymer film is a luminescent waveguide-encoded lattice (LWEL).

23. A method according to claim 1, wherein the polymerisation is characterised by the self-trapping of light.

24. A method according to claim 3, wherein the photoinitiator is a metallocene-based photoinitiator.

25. A method according to claim 10, wherein the sol comprises epoxide monomers and acrylate monomers in a wt ratio of between 5:1 to 1:5.

26. A method according to claim 11, wherein R¹ is C1-C8 alkyl.

27. A method according to claim 11, wherein Y is an alkylene group.

28. A method according to claim 6, wherein the patterned geometry is achieved by exposing the photosensitive sol to light in said geometry by using a mask.
